(19) United States
(12) Patent Application Publication
(10) Pub. No.: US 2025/0081765 A1
(43) Pub. Date: Mar. 6, 2025

(54) Display Substrate and Preparing Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Ziyang YU, Beijing (CN); Tiaomei ZHANG, Beijing (CN); Zhiliang JIANG, Beijing (CN); Ming HU, Beijing (CN); Pan ZHAO, Beijing (CN)

(21) Appl. No.: 18/282,801

(22) PCT Filed: Nov. 29, 2022
(86) PCT No.: PCT/CN2022/135137

§ 371 Date: Sep. 19, 2023

(51) Int. Cl. H10K 59/131; H10K 59/12; H10K 59/121

(52) U.S. Cl. CPC H10K 59/131; H10K 59/1201; H10K 59/1213

(57) ABSTRACT

A display substrate includes a base substrate (100), and multiple pixel circuits (11a, 11b) and multiple first auxiliary structures disposed on the base substrate (100). The multiple first auxiliary structures are located at edges of the multiple pixel circuits (11a, 11b). At least one first auxiliary structure is adjacent to at least one pixel circuit (11a, 11b). The multiple pixel circuits (11a, 11b) include at least one semiconductor layer located on the base substrate (100). An orthographic projection of the at least one first auxiliary structure on the base substrate (100) is at least partially identical to an orthographic projection of the semiconductor layer of the at least one pixel circuit (11a, 11b) on the base substrate (100).

### CROSS-REFERENCE TO RELATED APPLICATION

The present application is a U.S. National Phase Entry of International Application No. PCT/CN2022/135137 having an international filing date of Nov. 29, 2022, the entire content of which is hereby incorporated by reference.

### TECHNICAL FIELD

The present disclosure relates to, but is not limited to, the field of display technologies, and in particular to a display substrate and a preparing method therefor, and a display apparatus.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc.

### SUMMARY

The following is a summary of subject matters described herein in detail. The summary is not intended to limit the protection scope of claims.

Embodiments of the present disclosure provide a display substrate and a preparing method therefor, and a display apparatus.

In one aspect, this embodiment provides a display substrate, including a base substrate, multiple pixel circuits and multiple first auxiliary structures disposed on the base substrate. The multiple first auxiliary structures are located at edges of the multiple pixel circuits and at least one first auxiliary structure is adjacent to at least one pixel circuit. The multiple pixel circuits include at least one semiconductor layer located on the base substrate, and an orthographic projection of the at least one first auxiliary structure on the base substrate is at least partially identical to an orthographic projection of the at least one semiconductor layer of the at least one pixel circuit on the base substrate.

In some exemplary implementations, the multiple first auxiliary structures are arranged in a same manner as the multiple pixel circuits.

In some exemplary implementations, the multiple pixel circuits are arranged in an array along a first direction and a second direction; the at least one first auxiliary structure is aligned with the multiple pixel circuits in the first direction or in the second direction, or the at least one first auxiliary structure is misaligned with the multiple pixel circuits in the first direction or in the second direction; the first direction intersects with the second direction.

In some exemplary implementations, the multiple pixel circuits include at least one pixel circuit group, the at least one pixel circuit group includes two pixel circuits disposed adjacently in the first direction. The multiple first auxiliary structures includes at least one first auxiliary structure group and the at least one first auxiliary structure group includes two first auxiliary structures disposed adjacently in the first direction. An orthographic projection of the at least one first auxiliary structure group on the base substrate is at least partially identical to an orthographic projection of the at least one semiconductor layer of the at least one pixel circuit group on the base substrate.

In some exemplary implementations, two pixel circuits of the at least one pixel circuit group each includes: at least one first type transistor; the semiconductor layer includes an active layer of the at least one first type transistor; two first auxiliary structures of the at least one first auxiliary structure group each includes: at least one first auxiliary block; the at least one first auxiliary block and the active layer of the first type transistor are of a same layer structure. An orthographic projection of a first auxiliary block of the at least one first auxiliary structure group on the base substrate is identical to an orthographic projection of an active layer of a first type transistor of the at least one pixel circuit group on the base substrate.

In some exemplary implementations, active layers of first type transistors of two pixel circuits of the at least one pixel circuit group are symmetrical with respect to a centerline of the pixel circuit group in the first direction, and first auxiliary blocks of two first auxiliary structures of the first auxiliary structure group are symmetrical with respect to a centerline of the first auxiliary structure group in the first direction.

In some exemplary implementations, a pitch between active layers of first type transistors of two pixel circuits in the at least one pixel circuit group in the first direction is the same as a pitch between first auxiliary blocks of two first auxiliary structures in the at least one first auxiliary structure group in the first direction.

In some exemplary implementations, the multiple first auxiliary structure groups are located at edges of the multiple pixel circuit groups in the second direction, and pitches between the multiple first auxiliary structure groups and adjacent pixel circuit groups are same in the second direction; or, pitches between the first auxiliary structure groups disposed at interval and adjacent pixel circuit groups in the second direction are same, and pitches between the first auxiliary structure groups disposed adjacently and corresponding adjacent pixel circuit groups in the second direction are different; the second direction intersects with the first direction.

In some exemplary implementations, the multiple first auxiliary structure groups are located at edges of the multiple pixel circuit groups in the first direction, and pitches between the multiple first auxiliary structure groups and adjacent pixel circuit groups are same in the first direction; or, pitches between the first auxiliary structure groups disposed at interval and the adjacent pixel circuit groups in the first direction are same, and pitches between first auxiliary structure groups disposed adjacently and corresponding adjacent pixel circuit groups in the first direction are different.

In some exemplary implementations, the at least one first auxiliary structure group is aligned with multiple pixel circuit groups arranged along the first direction in the first direction.

In some exemplary implementations, the at least one first auxiliary structure group is aligned with multiple pixel circuit groups arranged along the second direction in the second direction, the second direction intersects with the first direction.

In some exemplary implementations, the display substrate further includes a second auxiliary structure, the second auxiliary structure includes multiple second auxiliary blocks located at edges of the multiple pixel circuits and arranged in an array; orthographic projections of the multiple second auxiliary blocks on the base substrate are not overlapped with an orthographic projection of the first auxiliary block on the base substrate.

In some exemplary implementations, the multiple second auxiliary blocks are located on a side of the first auxiliary block close to the base substrate.

In some exemplary implementations, the pixel circuit further includes: at least one second type transistor, the second type transistor and the first type transistor are of different transistor types; the multiple second auxiliary blocks and an active layer of the second type transistor are of a same layer structure.

In some exemplary implementations, the display substrate further includes multiple first auxiliary vias, the multiple first auxiliary vias and the multiple second auxiliary blocks are in one-to-one correspondence, an orthographic projection of at least one first auxiliary via on the base substrate is within an range of an orthographic projection of a corresponding second auxiliary block on the base substrate.

In some exemplary implementations, the base substrate includes a display area and a bezel area located on a periphery of the display area; the multiple first auxiliary structures are located in the bezel area, and the multiple pixel circuits are located in the display area.

In some exemplary implementations, the base substrate includes: a display area; the display area includes a first display area and a second display area located at least a side of the first display area; a transition area is provided between the first display area and the second display area; the multiple pixel circuits are located in the second display area, and the multiple first auxiliary structures are located in the transition area.

In some exemplary implementations, in a direction perpendicular to the display substrate, the display substrate further includes: a first semiconductor layer, a first conductive layer, a second conductive layer, a second semiconductor layer, a third conductive layer, a fourth conductive layer, and a fifth conductive layer disposed sequentially on the base substrate; the multiple first auxiliary structures at least include a first auxiliary block located in the second semiconductor layer.

In another aspect, this embodiment provides a display apparatus, which includes the aforementioned display substrate.

In another aspect, this embodiment provides a preparation method for a display substrate, which is used for preparing the display substrate as described above, the preparation method includes forming multiple pixel circuits and multiple first auxiliary structures on a base substrate. Among them, the multiple first auxiliary structures are located at edges of the multiple pixel circuits and at least one first auxiliary structure is adjacent to at least one pixel circuit. The multiple pixel circuits include at least one semiconductor layer located on the base substrate, and an orthographic projection of the at least one first auxiliary structure on the base substrate is at least partially identical to an orthographic projection of the at least one semiconductor layer of the at least one pixel circuit on the base substrate.

Other aspects may be understood upon reading and understanding the drawings and detailed description.

### BRIEF DESCRIPTION OF DRAWINGS

Accompanying drawings are used for providing an understanding of technical solutions of the present disclosure, constituting a part of the specification, and are used to explain the technical solutions of the present disclosure together with the embodiments of the present disclosure but are not intended to constitute limitations on the technical solutions of the present disclosure. Shapes and sizes of one or more components in the drawings do not reflect actual scales, but are only intended to schematically describe contents of the present disclosure.

FIG. 1 is a schematic diagram of peripheral wire thinning caused by a photolithography load effect.

FIG. 2 is a schematic diagram of a display substrate according to at least one embodiment of the present disclosure.

FIG. 3 is an equivalent circuit diagram of a pixel circuit according to at least one embodiment of the present disclosure.

FIG. 4 is a working timing diagram of the pixel circuit provided in FIG. 3.

FIG. 5 is a schematic partial plan view of a display area according to at least one embodiment of the present disclosure.

FIG. 6 is a schematic partial cross-section view along a Q-Q′ direction in FIG. 5.

FIG. 7 is a schematic plan view of a display area after a light shield layer is formed in FIG. 5.

FIG. 8 is a schematic plan view of a display area after a first semiconductor layer is formed in FIG. 5.

FIG. 9A is a schematic plan view of a display area after a first conductive layer is formed in FIG. 5.

FIG. 9B is a schematic plan view of the first conductive layer in FIG. 9A.

FIG. 10 is a schematic plan view of a display area after a second conductive layer is formed in FIG. 5.

FIG. 11 is a schematic plan view of a display area after a second semiconductor layer is formed in FIG. 5.

FIG. 12A is a schematic plan view of a display area after a third conductive layer is formed in FIG. 5.

FIG. 12B is a schematic plan view of the third conductive layer in FIG. 12A.

FIG. 13 is a schematic plan view of a display area after a sixth insulation layer is formed in FIG. 5.

FIG. 14A is a schematic plan view of a display area after a fourth conductive layer is formed in FIG. 5.

FIG. 14B is a schematic plan view of the fourth conductive layer in FIG. 14A.

FIG. 15 is a schematic plan view of a display area after a seventh insulation layer is formed in FIG. 5.

FIG. 16A is a schematic plan view of a display area after a fifth conductive layer is formed in FIG. 5.

FIG. 16B is a schematic plan view of the fifth conductive layer in FIG. 16A.

FIG. 17 is a schematic plan view of a display area after an eighth insulation layer is formed in FIG. 5.

FIG. 18 is a schematic partial enlarged view of an area D1 in FIG. 2.

FIG. 19 is a schematic plan view of a light shield layer in FIG. 18.

FIG. 20 is a schematic plan view of a first semiconductor layer in FIG. 18.

FIG. 21 is a schematic plan view of a second semiconductor layer in FIG. 18.

FIG. 22 is a partial schematic view of the second semiconductor layer in FIG. 21.

FIG. 23 is a schematic plan view of a first semiconductor layer and a second semiconductor layer in FIG. 18.

FIG. 24 is a schematic plan view of a display substrate after a sixth insulation layer is formed in FIG. 18.

FIG. 25 is a schematic plan view of a fourth conductive layer in FIG. 18.

FIG. 26 is a schematic plan view of a fifth conductive layer in FIG. 18.

FIGS. 27A to 27C are other schematic plan views of a second semiconductor layer in FIG. 18.

FIG. 28 is another schematic diagram of a display substrate according to at least one embodiment of the present disclosure.

FIG. 29 is a schematic partial plan view of an area D2 in FIG. 28.

FIG. 30 is a schematic plan view of a first semiconductor layer in FIG. 29.

FIG. 31 is a schematic plan view of a first semiconductor layer, a first conductive layer, and a second conductive layer in FIG. 29.

FIG. 32 is a schematic plan view of a second semiconductor layer in FIG. 29.

FIG. 33 is a schematic plan view after a sixth insulation layer is formed in FIG. 29.

FIG. 34 is a schematic plan view of a fourth conductive layer in FIG. 29.

FIGS. 35A to 35C are other schematic plan views of a second semiconductor layer in FIG. 29.

FIG. 36 is a schematic diagram of a display apparatus according to at least one embodiment of the present disclosure.

### DETAILED DESCRIPTION

Embodiments of the present disclosure will be described below in combination with the drawings in detail. Implementations may be implemented in multiple different forms. Those of ordinary skills in the art may easily understand such a fact that implementations and contents may be transformed into one or more forms without departing from the purpose and scope of the present disclosure. Therefore, the present disclosure should not be explained as being limited to contents described in following implementations only. The embodiments in the present disclosure and features in the embodiments may be combined randomly with each other if there is no conflict.

In the drawings, a size of one or more constituent elements, a thickness of a layer, or an area is sometimes exaggerated for clarity. Therefore, an implementation of the present disclosure is not necessarily limited to the size, and shapes and sizes of various components in the drawings do not reflect true scales. In addition, the drawings schematically illustrate ideal examples, and an implementation of the present disclosure is not limited to shapes, numerical values, or the like shown in the drawings.

Ordinal numerals such as “first”, “second”, and “third” in the specification are set to avoid confusion of constituent elements, but not to set a limit in quantity. In the present disclosure, “multiple” may include two or more than two.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, they are merely for facilitating the description of the specification and simplifying the description, rather than indicating or implying that a referred device or element must have a particular orientation and be constructed and operated in the particular orientation. Therefore, they cannot be understood as limitations on the present disclosure. The positional relationships between the constituent elements vary as appropriate according to a direction of a described constituent element. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, a connection may be a fixed connection, or a detachable connection, or an integrated connection. It may be a mechanical connection or an electrical connection. It may be a direct mutual connection, or an indirect connection through a middleware, or an internal communication between two elements. Those of ordinary skills in the art may understand meanings of the aforementioned terms in the present disclosure according to situations.

In the specification, “electrical connection” includes a case that constituent elements are connected together through an element with a certain electrical effect. The “an element with a certain electrical effect” is not particularly limited as long as electrical signals between the connected constituent elements may be transmitted. Examples of “an element with a certain electrical effect” not only include an electrode and a wiring, but further include a switch element such as a transistor, a resistor, an inductor, a capacitor, another element with one or more functions, etc.

In the specification, a transistor refers to an element which at least includes three terminals, i.e., a gate electrode (a gate), a drain electrode, and a source electrode. The transistor has a channel area between the drain electrode (drain electrode terminal, drain area, or drain) and the source electrode (source electrode terminal, source area, or source), and a current may flow through the drain electrode, the channel region and the source electrode. In the present disclosure, the channel area refers to an area which a current mainly flows through.

In this specification, for distinguishing the two electrodes, except the gate, of the transistor, one electrode is called a first electrode, and the other electrode is called a second electrode. The first electrode may be the source or the drain, and the second electrode may be the drain or the source. In addition, a gate of the transistor may be called a control electrode. In cases that transistors with opposite polarities are used, a current direction changes during operation of a circuit, or the like, functions of the “source electrode” and the “drain electrode” are sometimes interchangeable. Therefore, the “source electrode” and the “drain electrode” are interchangeable in the specification.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 850 and below 95°.

A triangle, rectangle, trapezoid, pentagon, or hexagon, etc. in this specification is not strictly defined, and it may be an approximate triangle, rectangle, trapezoid, pentagon, or hexagon, etc. There may be some small deformations caused by tolerance, and there may be a chamfer, an arc edge, and a deformation, etc.

In the specification, a “film” and a “layer” are interchangeable. For example, a “conductive layer” may be replaced with a “conductive film” sometimes. Similarly, an “insulation film” may be replaced with an “insulation layer” sometimes.

In this specification, “about” and “substantially” refer to that a boundary is not defined strictly and a case within a process and measurement error range is allowed. In this specification, “identical” may be a case where the values differ by less than 10%, or a case where the similarity is greater than or equal to 90%.

In the present disclosure, “A extends in a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A extends in a B direction” in the present disclosure means “a main portion of A extends in a B direction”.

In this specification, a width denotes a length of a wire in a direction perpendicular to an extension direction.

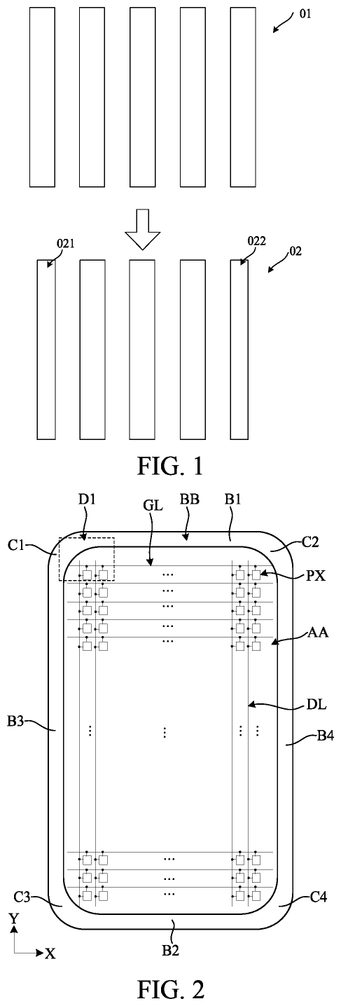

FIG. 1 is a schematic diagram of peripheral wire thinning caused by a photolithography load effect. In some examples, a single photolithography process may primarily include: coating a photoresist on a film layer to be etched; exposing the photoresist by using an exposure light source to pass through a mask; developing and fixing the photoresist; etching the film layer to be etched which is not protected by the photoresist; removing the photoresist to obtain the desired pattern on the film layer to be etched. A pattern 01 shown in FIG. 1 is a pattern of a mask, and a pattern 02 is a pattern of a photoresist after development. Widths of multiple patterns extending in a same direction in the pattern 01 are the same; widths of patterns at edges (e.g., Pattern 021 and Pattern 022) in the pattern 02 are smaller than widths of patterns in the middle area. Due to different photolithography load effects, for dense patterns, patterns at the utmost edge will be thinner after development, which leads to inconsistency with patterns in other areas.

In some implementations, due to the load effect of photolithography process or other process environment differences, some film layers in the edge area of the display substrate will lead to abnormal CD (Critical Dimension) or characteristics of the transistor, resulting in poor bright and dark spots at an edge.

This embodiment provides a display substrate, including a base substrate, multiple pixel circuits and multiple first auxiliary structures provided on the base substrate. The multiple first auxiliary structures are located at edges of the multiple pixel circuits, and at least one first auxiliary structure is adjacent to the at least one pixel circuit. The multiple pixel circuits include at least one semiconductor layer located on the base substrate. An orthographic projection of the at least one first auxiliary structure on the base substrate is at least partially identical to an orthographic projection of the at least one semiconductor layer of the at least one pixel circuit on the base substrate. For example, the first auxiliary structure may be identical to film layer structure and shape of at least one semiconductor layer (e.g., including an active layer of a transistor) of the pixel circuit, or the first auxiliary structure may be identical to structures and shapes of at least one semiconductor layer (e.g., including an active layer of a transistor) and at least one conductive layer (e.g., including a gate electrode or a source-drain electrode of a transistor) of the pixel circuit. In some examples, the first auxiliary structure may not be provided with electrical connections to avoid affecting other signal transmissions. The first auxiliary structure in this example can be a dummy structure.

By disposing multiple first auxiliary structures at edges of multiple pixel circuits, the display substrate provided by this embodiment can improve the situation of poor bright and dark spots at an edge caused by the photolithography load effect or other process environment differences, thereby improving the display effect of the display substrate.

In some exemplary implementations, the multiple first auxiliary structures may be arranged in a same manner as the multiple pixel circuits. For example, the multiple pixel circuits may be arranged in an array along a first direction and a second direction and the multiple first auxiliary structures may be regularly arranged in a first direction or a second direction. An arrangement mode of the multiple first auxiliary structures is the same as an arrangement mode of the multiple pixel circuits, which is beneficial to ensuring a consistency of edge patterns of the multiple pixel circuits.

In some exemplary implementation, the multiple pixel circuits may be arranged in an array in a first direction and a second direction and at least one first auxiliary structure is aligned with the multiple pixel circuits in the first direction or in the second direction, and the first direction may intersect with the second direction. By disposing the first auxiliary structure aligned with the pixel circuit at edges of the multiple pixel circuits, the first auxiliary structure can be guaranteed to be of an edge pattern of the pixel circuit in the preparing process, thereby avoiding a size change of the pixel circuit located at the edge due to the photolithography load effect or other process environment differences. In some other examples, at least one first auxiliary structure may be misaligned with the multiple pixel circuits in the first direction or in the second direction. By providing a misaligned first auxiliary structure and ensuring that the topography of the first auxiliary structure and the pixel circuit are at least partially identical, the adverse effects caused by the photolithography load effect or other process environment differences can be improved.

In some exemplary implementations, the multiple pixel circuits may include at least one pixel circuit group, and the at least one pixel circuit group may include two pixel circuits disposed adjacently in the first direction. The multiple first auxiliary structures include at least one first auxiliary structure group and the at least one first auxiliary structure group includes two first auxiliary structures disposed adjacently in the first direction. An orthographic projection of the at least one first auxiliary structure group on the base substrate may be at least partially identical to an orthographic projection of the at least one semiconductor layer of the at least one pixel circuit group on the base substrate. In some examples, two pixel circuits of the at least one pixel circuit group each includes: at least one first type transistor; the semiconductor layer may include an active layer of at least one transistor of the first type. Two first auxiliary structures of the at least one first auxiliary structure group each includes: at least one first auxiliary block; the at least one first auxiliary block and the active layer of the first type transistor may be of a same layer structure. An orthographic projection of the first auxiliary block of the at least one first auxiliary structure group on the base substrate may be identical to an orthographic projection of the active layer of the first type transistor of the at least one pixel circuit group on the base substrate. In this example, the first auxiliary block and the active layer of the first type transistor are arranged in a same layer structure, which is beneficial to improving the abnormality of the edge of the semiconductor layer where the active layer of the first type transistor is located due to the photolithography load effect or other process environment differences.

In some exemplary implementations, the active layers of the first type transistors of two pixel circuits of at least one pixel circuit group may be symmetrical with respect to a centerline of the pixel circuit group in the first direction, and first auxiliary blocks of two first auxiliary structures of the first auxiliary structure group may be symmetrical with respect to a centerline of the first auxiliary structure group in the first direction. In this example, “A and B are symmetrical with respect to C” may be that A and B have portions which are more than 90% overlapped with respect to C. By disposing the symmetrical structure of the pixel circuit group and the first auxiliary structure group, it is beneficial to reducing an occupied space of the pixel circuit and realizing a high-resolution display substrate or a full-screen display substrate.

In some exemplary implementations, the multiple first auxiliary structure groups are located at edges of the multiple pixel circuit groups in the second direction, pitches between the multiple first auxiliary structure groups and adjacent pixel circuit groups may be the same in the second direction; or, pitches between the first auxiliary structure groups disposed at interval and the adjacent pixel circuit groups may be the same in the second direction, and pitches between the first auxiliary structure groups disposed adjacently and the corresponding adjacent pixel circuit groups may be different in the second direction. The second direction interacts with the first direction. By adjusting the position of the first auxiliary structure group, this example can adapt to a shape of an edge area of the pixel circuit group, which is beneficial to improving the abnormality due to the photolithography load effect or other process environment differences.

In some exemplary implementations, the multiple first auxiliary structure groups are located at edges of the multiple pixel circuit groups in the first direction, pitches between the multiple first auxiliary structure groups and adjacent pixel circuit groups may be the same in the first direction; or, the pitches between the first auxiliary structure groups disposed at interval and the adjacent pixel circuit groups may be the same in the first direction, and the pitches between the first auxiliary structure groups disposed adjacently and the corresponding adjacent pixel circuit groups may be different in the first direction. By adjusting the position of the first auxiliary structure group, this example can adapt to the shape of the edge area of the pixel circuit group, which is beneficial to improving the abnormality due to the photolithography load effect or other process environment differences.

In some exemplary implementations, the display substrate may further include a second auxiliary structure. The second auxiliary structure may include multiple second auxiliary blocks located at edges of the multiple pixel circuits and arranged in an array; orthographic projections of the multiple second auxiliary blocks on the base substrate are not overlapped with an orthographic projection of the first auxiliary block on the base substrate. This example helps to improve the pattern uniformity of the edge area of the pixel circuit during the preparing process by providing the second auxiliary structure.

Solutions of the embodiments will be described below through some examples.

FIG. 2 is a schematic diagram of a display substrate according to at least one embodiment of the present disclosure. In some examples, as shown in FIG. 2, the display substrate may include a display area AA and a bezel area BB surrounding the display area AA. The display substrate may have a substantially rectangular shape. The display substrate may include a pair of long sides parallel to each other in the first direction X and a pair of short sides parallel to each other in the second direction Y. That is, a length of the display substrate in the first direction X is smaller than a length in the second direction Y. The first direction X may intersect with the second direction Y, for example, the first direction X may be perpendicular to the second direction Y. However, this embodiment is not limited thereto. In some other examples, the display substrate may be a closed polygon including linear edges, a circle or an ellipse including a curved edge, a semicircle or semi-ellipse including a linear edge and a curved edge, or the like. In some examples, when the base substrate has a linear side, at least some corners of the base substrate may be curved. When the base substrate is in a shape of a rectangle, a portion at a position where adjacent linear sides intersect with each other may be replaced by a curve with a predetermined curvature. Among them, the curvature may be set according to different positions of the curve. For example, the curvature may be changed according to a starting position of the curve, a length of the curve, etc.

In some examples, as shown in FIG. 2, the bezel area BB may include an upper bezel B1, a lower bezel B2, a left bezel B3, a right bezel B4, a first corner C1 connecting the upper bezel Bf1 and the left bezel B3, a second corner C2 connecting the upper bezel B1 and the right bezel B4, a third corner C3 connecting the lower bezel B2 and the left bezel B3, and a fourth corner C4 connecting the lower bezel B2 and the right bezel B4.

In some examples, as shown in FIG. 2, the display area AA may at least include multiple sub-pixels PX, multiple gate lines GL, and multiple data lines DL. The multiple gate lines GL may extend in the first direction X and are sequentially arranged in the second direction Y; the multiple data lines DL may extend in the second direction Y and are sequentially arranged in the first direction X. Orthographic projections of the multiple gate lines GL on the base substrate may intersect with orthographic projections of the multiple data lines DL on the base substrate to form multiple sub-pixel areas, and one sub-pixel PX is disposed in each sub-pixel area. The multiple data lines DL are electrically connected with multiple sub-pixels PX and the multiple data lines DL may be configured to provide data voltages to the multiple sub-pixels PX. The multiple gate lines GL are electrically connected with the multiple sub-pixels PX and the multiple gate lines GL may be configured to provide gate control signals to the multiple sub-pixels PX. However, this embodiment is not limited thereto.

In some examples, a pixel unit may include three sub-pixels, which may be respectively a red sub-pixel, a green sub-pixel, and a blue sub-pixel. However, this embodiment is not limited thereto. In some examples, one pixel unit may include four sub-pixels, which may be a red sub-pixel, a green sub-pixel, a blue sub-pixel, and a white sub-pixel respectively.

In some examples, at least one sub-pixel may include a pixel circuit and a light emitting element. The pixel circuit may be configured to drive a light emitting element connected with the pixel circuit. For example, the pixel circuit may be configured to provide a drive current for driving the light emitting element to emit light. The pixel circuit may include multiple transistors and at least one capacitor. For example, the pixel circuit may be a 3T1C structure, an 8T1C structure, a 7T1C structure, or a 5T1C structure. In the above circuit structure, T refers to a thin film transistor, C refers to a capacitor, a number before T represents a quantity of thin film transistors in the circuit, and a number before C represents a quantity of capacitors in the circuit.

In some examples, the light emitting element may be any of a Light Emitting Diode (LED), an Organic Light Emitting Diode (OLED), a Quantum dot Light Emitting Diode (QLED), a micro LED (including: mini-LED or micro-LED), and the like. For example, the light emitting element may be an OLED, and the light emitting element may emit red light, green light, blue light, or white light, etc. under drive of its corresponding pixel circuit. A color of light emitted from the light emitting element may be determined as required. In some examples, the light emitting element may include an anode, a cathode, and an organic emitting layer disposed between the anode and the cathode. The anode of the light emitting element may be electrically connected with a corresponding pixel circuit. However, this embodiment is not limited thereto.

In some examples, a shape of the light emitting element may be a rectangle, a rhombus, a pentagon, or a hexagon. When a pixel unit includes three sub-pixels, light emitting elements of the three sub-pixels may be arranged side by side horizontally, side by side vertically, or in a shape of a Chinese character “ [symbol] ”. When a pixel unit includes four sub-pixels, light emitting elements of the four sub-pixels may be arranged side by side horizontally, side by side vertically, or in a square-shaped arrangement. However, this embodiment is not limited thereto.

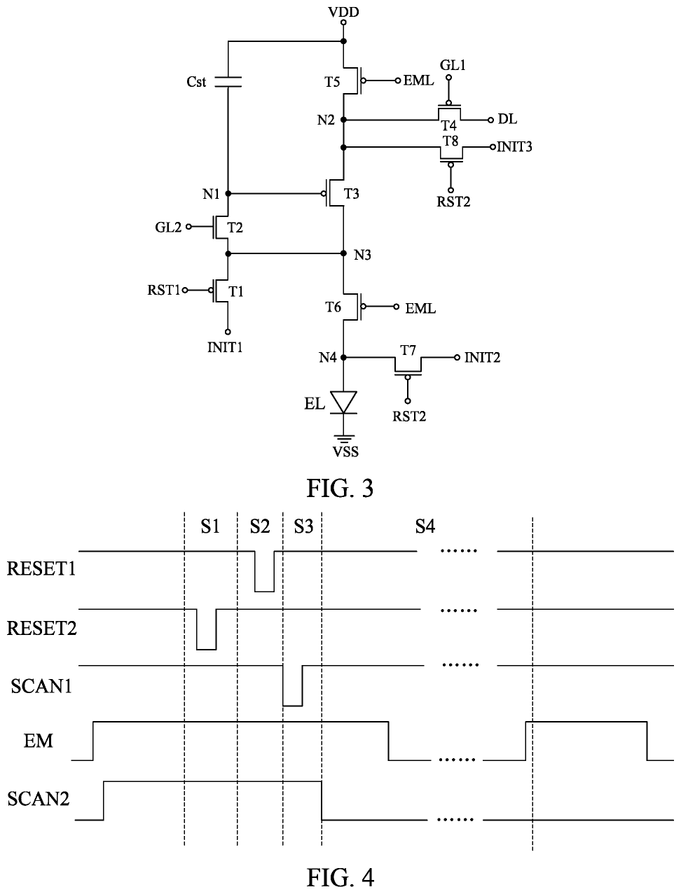

FIG. 3 is an equivalent circuit diagram of a pixel circuit according to at least one embodiment of the present disclosure. The pixel circuit of the present exemplary embodiment is described by taking an 8T1C structure as an example.

In some examples as, shown in FIG. 3, the pixel circuit of this example may include eight transistors (i.e., a first transistor T1 to an eighth transistor T8) and a storage capacitor Cst. The first transistor T1 is also referred to as a first reset transistor, the second transistor T2 is also referred to as a threshold compensation transistor, the third transistor T3 is also referred to as a drive transistor, the fourth transistor T4 is also referred to as a data writing transistor, the fifth transistor T5 is also referred to as a first light emitting control transistor, the sixth transistor T6 is also referred to as a second light emitting control transistor, the seventh transistor T7 is also referred to as a second reset transistor, and the eighth transistor T8 is also referred to as a third reset transistor. The light emitting element EL may include an anode, a cathode and an organic emitting layer disposed between the anode and the cathode.

In some examples, the second transistor T2 may be a first type transistor, for example, may be an N-type transistor. The first transistor T1, the third transistor T3 to the eighth transistor T8 may be second type transistors, for example may be P-type transistors. However, this embodiment is not limited thereto. For example, the transistors of the first pixel circuit may be P-type transistors altogether or may be N-type transistors altogether.

In some examples, second type transistors (e.g., including the first transistor T1, the third transistor T3 to the eighth transistor T8) of the pixel circuit may adopt low temperature poly-crystalline silicon thin film transistors, and first type transistors (e.g., including the second transistor T2) of the pixel circuit may adopt oxide thin film transistors. An active layer of a low temperature poly-crystalline silicon thin film transistor is made of Low Temperature Poly-crystalline Silicon (LTPS), and an active layer of an oxide thin film transistor is made of an oxide semiconductor (Oxide). A low temperature poly-crystalline silicon thin film transistor has advantages, such as a high mobility, and fast charging, etc., while an oxide thin film transistor has advantages, such as a low leakage current, etc. The low temperature poly-silicon thin film transistor and the oxide thin film transistor are integrated on one display substrate to form a low temperature poly-crystalline oxide (LTPS+ Oxide) display substrate, and advantages of both the low temperature poly-crystalline silicon thin film transistor and the oxide thin film transistor can be utilized, which can achieve low frequency drive, reduce power consumption, and improve display quality.

In some examples, as shown in FIG. 3, the pixel circuit may be electrically connected with the first scan line GL1, the second scan line GL2, the data line DL, the first power line VDD, the second power line VSS, the light emitting control line E-L, the first initial signal line INIT1, the second initial signal line INIT2, the third initial signal line INIT3, the first reset control line RST1, and the second reset control line RST2. The first power line VDD is configured to provide a constant first voltage signal to the pixel circuit, the second power line VSS is configured to provide a constant second voltage signal to the pixel circuit, and the first voltage signal is greater than the second voltage signal. The first scan line GL1 may be configured to provide a first scan signal SCAN1 to the pixel circuit. The second scan line GL2 may be configured to provide a second scan signal SCAN2 to the pixel circuit. The data line DL may be configured to provide a data signal to the pixel circuit. The light emitting control line EML may be configured to provide a light emitting control signal EM to the pixel circuit. The first reset control line RST1 may be configured to provide a first reset control signal RESET1 to the pixel circuit. The second reset control line RST2 may be configured to provide a second reset control signal RESET2 to the pixel circuit.

In some examples, as shown in FIG. 3, a gate of the third transistor T3 is electrically connected with the first node N1, a first electrode of the third transistor T3 is electrically connected with a second node N2, and a second electrode of the third transistor T3 is electrically connected with a third node N3. A gate electrode of the fourth transistor T4 is electrically connected with the first scan line GL1, a first electrode of the fourth transistor T4 is electrically connected with the data line DL, and a second electrode of the fourth transistor T4 is electrically connected with the second node N2. A gate electrode of the second transistor T2 is connected to the second scan signal line GL2, a first electrode of the second transistor T2 is electrically connected with a first node N1, and a second electrode of the second transistor T2 is electrically connected with a third node N3. A gate electrode of the fifth transistor T5 is electrically connected with the light emitting control line EML, a first electrode of the fifth transistor T5 is electrically connected with the first power line VDD, and a second electrode of the fifth transistor T5 is electrically connected with the second node N2. A gate electrode of the sixth transistor T6 is electrically connected with the light emitting control line EML, a first electrode of the sixth transistor T6 is electrically connected with the third node N3, and a second electrode of the sixth transistor T6 is electrically connected with the fourth node N4. A gate electrode of the first transistor T1 is electrically connected with a first reset control line RST1, a first electrode of the first transistor T1 is electrically connected with a first initial signal line INIT1, and a second electrode of the first transistor T1 is electrically connected with the third node N3. A gate electrode of the seventh transistor T7 is electrically connected with the second reset control line RST2, a first electrode of the seventh transistor T7 is electrically connected with the second initial signal line INIT2, and a second electrode of the seventh transistor T7 is electrically connected with the fourth node N4. A gate electrode of the eighth transistor T8 is electrically connected with the second reset control line RST2, a first electrode of the eighth transistor T8 is electrically connected with the third initial signal line INIT3, and a second electrode of the eighth transistor T8 is electrically connected with the second node N2. A first capacitance electrode plate of the storage capacitor Cst is electrically connected with the first node N1 and a second capacitance electrode plate of the storage capacitor Cst is electrically connected with the first power line VDD.

In this example, the first node N1 is a connection point for the storage capacitor Cst, the second transistor T2, and the third transistor T3, the second node N2 is a connection point for the fifth transistor T5, the fourth transistor T4, the eighth transistor T8, and the third transistor T3, the third node N3 is a connection point for the first transistor T1, the third transistor T3, the second transistor T2, and the sixth transistor T6, and the fourth node N4 is a connection point for the sixth transistor T6, the seventh transistor T7, and the light emitting element EL.

FIG. 4 is a working timing diagram of the pixel circuit provided in FIG. 3. A working process of the pixel circuit shown in FIG. 3 will be described below with reference to FIG. 4. Herein, the first transistor T1, the third transistor T3 to the eighth transistor T8 of the pixel circuit are P-type transistors, and the second transistor T2 is an N-type transistor.

In some examples, as shown in FIG. 3 and FIG. 4, during one frame display period, the working process of the pixel circuit may at least include a first stage S1, a second stage S2, a third stage S3, and a fourth stage S4.

The first stage S1 is referred to as a first reset stage. The second reset control signal RESET2 provided by the second reset control line RST2 is a low level signal to turn on the seventh transistor T7 and the eighth transistor T8, and the second scan signal SCAN2 provided by the second scan line GL2 is a high level signal to turn on the second transistor T2. The eighth transistor T8 is turned on so that the third initial signal provided by the third initial signal line INIT3 is provided to the second node N2. The seventh transistor T7 is turned on so that the second initial signal provided by the second initial signal line INIT2 is provided to the fourth node N4 to initialize the fourth node N4. The first scan signal SCAN1 provided by the first scan line GL1 is a high level signal, the first reset control signal RESET1 provided by the first reset control line RST1 is a high level signal, and the light emitting control signal EM provided by the light emitting control line EML is a high level signal, so that the fourth transistor T4, the first transistor T1, the fifth transistor T5 and the sixth transistor T6 are turned off. In this stage, the light emitting element EL does not emit light.

The second stage S2 is referred to as a second reset stage. The first reset control signal RESET1 provided by the first reset control line RST1 is a low level signal, and the first transistor T1 is turned on; the second scan signal SCAN2 provided by the second scan line GL2 is a high level signal, and the second transistor T2 is turned on. The first transistor T1 and the second transistor T2 are turned on such that a first initial signal line provided by the first initial signal line INIT1 is provided to the first node N1 to initialize the first node N1. The second reset control signal RESET2 provided by the second reset control line RST2 is a high level signal, the first scan signal SCAN1 provided by the first scan line GL1 is a high level signal, and the light emitting control signal EM provided by the light emitting control line EML is a high level signal, so that the seventh transistor T7, the eighth transistor T8, the fourth transistor T4, the fifth transistor T5 and the sixth transistor T6 are turned off. In this stage, the light emitting element EL does not emit light.

The third stage S3 is referred to as a data writing stage or a threshold compensation stage. The first scan signal SCAN1 provided by the first scan line GL1 is a low level signal, and the fourth transistor T4 is turned on; the second scan signal SCAN2 provided by the second scan line GL2 is a high level signal, and the second transistor T2 is turned on. At this stage, the first capacitor electrode plate of the storage capacitor Cst is low level and the third transistor T3 is turned on. The second transistor T2, the fourth transistor T4, and the third transistor T3 are turned on, so that a data voltage output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage of the first capacitor electrode plate (i.e., the first node N1) of the storage capacitor Cst is Vdata−|Vth|, wherein Vdata is the data voltage output by the data line DL, and Vth is the threshold voltage of the third transistor T3. The first reset control signal RESET1 provided by the first reset control line RST1 is a high level signal, the second reset control signal RESET2 provided by the second reset control line RST2 is a high level signal, and the light emitting control signal EM provided by the light emitting control line EML is a high level signal, so that the first transistor T1, the seventh transistor T7, the eighth transistor T8, the fifth transistor T5 and the sixth transistor T6 are turned off.

In the fourth stage S4, the light emitting control signal EM provided by the light emitting control line EML can be switched from a high level signal to a low level signal, so that the fifth transistor T5 and the sixth transistor T6 are turned on. The second scan signal SCAN2 provided by the second scan line GL2 is a low level signal, so that the second transistor T2 is turned off. The first scan signal SCAN1 provided by the first scan line GL1, the first reset control signal RESET1 provided by the first reset control line RST1, and the second reset control signal RESET2 provided by the second reset control line RST2 are high level signals, so that the fourth transistor T4, the first transistor T1, the seventh transistor T7, and the eighth transistor T8 are turned off. The first voltage signal VDD outputted by the first power line PL1 may provide a drive voltage to the anode of the light emitting element EL through the fifth transistor T5, the third transistor T3, and the sixth transistor T6 which are turned on, driving the light emitting element EL to emit light.

In a drive process of the pixel circuit, a drive current flowing through the third transistor T3 is determined by a voltage difference between the gate and the first electrode of the third transistor T3. Since the voltage of the first node N1 is Vdata−|Vth|, the drive current of the third transistor T3 is as follows.

I=K×(Vgs−Vth)²=K×[(Vdd−Vdata+|Vth|)−Vth]²=K×[Vdd−Vdata]²;
I is the drive current flowing through the third transistor T3, that is, a drive current for driving the light emitting element, K is a constant, Vgs is the voltage difference between the gate electrode and the first electrode of the third transistor T3, Vth is the threshold voltage of the third transistor T3, Vdata is the data voltage output by the data line DL, and Vdd is the first voltage signal output by the first power line VDD.

It may be seen from the above formula that a current flowing through the light emitting element is independent of the threshold voltage of the third transistor T3. Therefore, the pixel circuit according to this embodiment can better compensate the threshold voltage of the third transistor T3. Moreover, the pixel circuit provided in this embodiment can improve the poor display caused by low frequency and improve the display effect of the light emitting element.

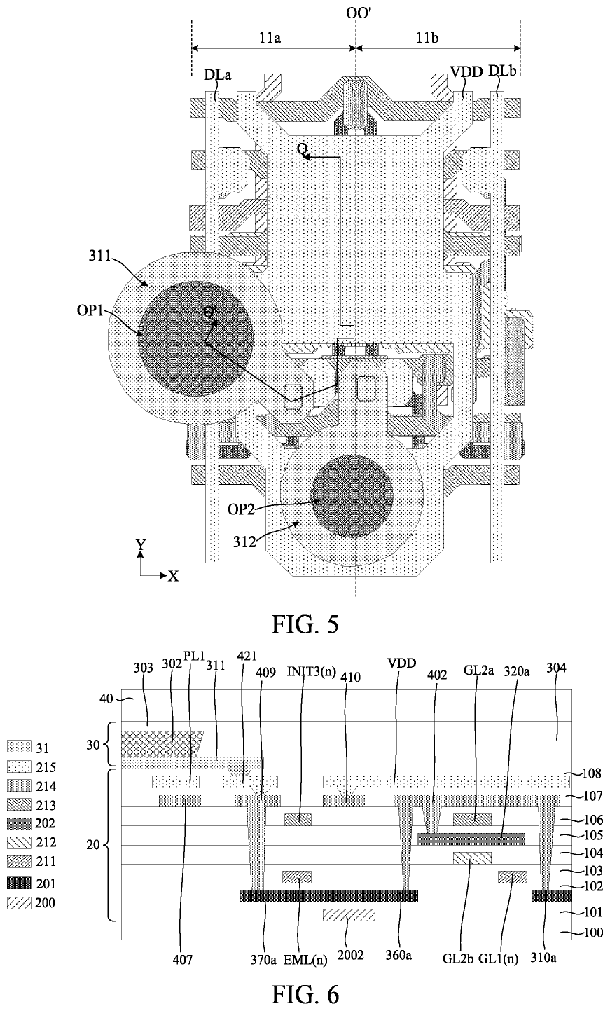

FIG. 5 is a schematic partial plan view of a display area according to at least one embodiment of the present disclosure. FIG. 6 is a schematic partial cross-section view along a Q-Q′ direction in FIG. 5. In some examples, the display area may include multiple pixel circuits, the multiple pixel circuits may be divided into multiple pixel circuit groups, each of pixel circuit groups may include two pixel circuits disposed adjacently in the first direction X. In FIG. 5, illustration is made by taking a pixel circuit group (such as, including two pixel circuits 11a and 11b adjacent in the first direction X) as an example.

In some examples, as shown in FIG. 5, in a plane parallel to the display substrate, two pixel circuits 11a and 11b within a pixel circuit group may be symmetrical with respect to a first centerline 00′ of the pixel circuit group in the first direction X. By setting the two pixel circuits in the pixel circuit group to be a mirror image structure symmetrical with respect to the first centerline 00′, the occupied space of the pixel circuits can be saved.

In some examples, as shown in FIG. 5 and FIG. 6, in a direction perpendicular to the display substrate, the display substrate may include a base substrate 100, and a circuit structure layer 20, a light emitting structure layer 30, and an encapsulation structure layer 104 disposed on the base substrate 100. The circuit structure layer 20 may include a light shield layer 200, a first semiconductor layer 201, a first conductive layer (or a first gate metal layer) 211, a second conductive layer (or a second gate metal layer) 212, a second semiconductor layer 202, a third conductive layer (or a third gate metal layer) 213, a fourth conductive layer (or a first source-drain metal layer) 214, and a fifth conductive layer (or a second source-drain metal layer) 215 disposed sequentially on the base substrate 100. A first insulation layer 101 may be disposed between the first semiconductor layer 201 and the light shield layer 200, a second insulation layer 102 may be disposed between the first semiconductor layer 201 and the first conductive layer 211, a third insulation layer 103 may be disposed between the first conductive layer 211 and the second conductive layer 212, a fourth insulation layer 104 may be disposed between the second conductive layer 212 and the second semiconductor layer 202, a fifth insulation layer 105 may be disposed between the second semiconductor layer 202 and the third conductive layer 213, a sixth insulation layer 106 may be disposed between the third conductive layer 213 and the fourth conductive layer 214, a seventh insulation layer 107 may be disposed between the fourth conductive layer 214 and the fifth conductive layer 215, and an eighth insulation layer 108 may be disposed on a side of the fifth conductive layer 215 away from the base substrate 100. In some examples, the first insulation layer 101 to the sixth insulation layer 106 may be inorganic insulation layers, and the seventh insulation layer 107 and the eighth insulation layer 108 may be organic insulation layers. However, this embodiment is not limited thereto.

In some examples, as shown in FIG. 6, the light emitting structure layer 30 may include at least an anode layer 31 (e.g., including anodes 311 and 312), a pixel definition layer 304, an organic emitting layer (e.g., an organic emitting layer 302), and a cathode layer 303 disposed sequentially on the circuit structure layer 20. The anode layer 31 may be electrically connected with the pixel circuit of the circuit structure layer 20, for example, the anode 311 may be electrically connected with the pixel circuit 11a and the anode 312 may be electrically connected with the pixel circuit 11b. The pixel definition layer 304 may be opened with multiple pixel openings (e.g., pixel openings OP1 and OP2). The organic emitting layer may be connected with the anode layer 31 (for example, the organic emitting layer 302 may be in contact with the anode 311 through the pixel opening OP1). The cathode layer 303 may be connected with the organic emitting layer. For example, the organic emitting layer 302 may emit light of corresponding colors driven by the anode 311 of the anode layer 31 and the cathode layer 303.

In some examples, as shown in FIG. 6, the encapsulation structure layer 40 may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is disposed between the first encapsulation layer and the third encapsulation layer to form an inorganic material/organic material/inorganic material stacked structure, which may ensure that outside water vapor cannot enter the light emitting structure layer 30. In some possible implementations, the display substrate may include other film layers, such as a touch structure layer, and a color filter layer, which is not limited here in this embodiment.

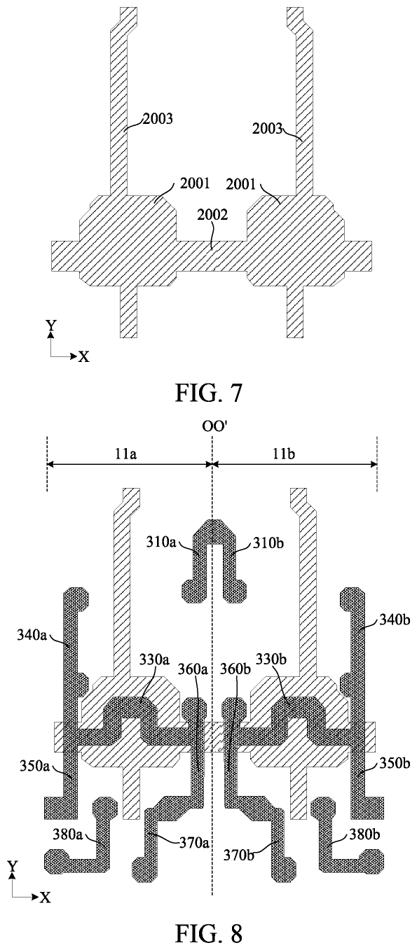

FIG. 7 is a schematic plan view of a display area after a light shield layer is formed in FIG. 5. In some examples, as shown in FIG. 7, the light shield layer of the display area may include a light shield electrode 2001 a first light shield connection electrode 2002 and a second light shield connection electrode 2003. The first light shielding connection electrode 2002 may extend in the first direction X and the second light shielding connection electrode 2003 may extend in the second direction Y. Two light shield electrodes 2001 adjacent in the first direction X may be electrically connected by the first light shield connection electrode 2002 and the two light shield electrodes 2001 adjacent in the second direction Y may be electrically connected by the second light shield connection electrode 2003.

FIG. 8 is a schematic plan view of a display area after a first semiconductor layer is formed in FIG. 5. In some examples, as shown in FIG. 7 and FIG. 8, the first semiconductor layer of the display area may include a first active layer 310a of the first transistor, a third active layer 330a of the third transistor, a fourth active layer 340a of the fourth transistor, a fifth active layer 350a of the fifth transistor, a sixth active layer 360a of the sixth transistor, a seventh active layer 370a of the seventh transistor, and an eighth active layer 380a of the eighth transistor of one pixel circuit 11a, and a first active layer 310b of the first transistor, a third active layer 330b of the third transistor, a fourth active layer 340b of the fourth transistor, a fifth active layer 350b of the fifth transistor, a sixth active layer 360b of the sixth transistor, a seventh active layer 370b of the seventh transistor, and an eighth layer 380b of the eighth transistor of the other pixel circuit 11b, in the pixel circuit group.

In some examples, as shown in FIG. 8, the first active layer 310a of the first transistor of the pixel circuit 11a and the first active layer 310b of the first transistor of the pixel circuit 11b may be symmetrical about the first centerline 00′. The first active layer 310a of the first transistor of the pixel circuit 11a and the first active layer 310b of the first transistor of the pixel circuit 11b may be of an integrated structure, for example, the integrated structure may be in an inverted U shape. The first active layer 310a of the first transistor of the pixel circuit 11a and the first active layer 310b of the first transistor of the pixel circuit 11b may be located on a side of the third active layers 330a and 330b away from the eighth active layers 380a and 380b in the second direction Y.

In some examples, as shown in FIG. 8, the third active layer 330a of the third transistor to the eighth active layer 380a of the eighth transistor of the pixel circuit 11a and the third active layer 330b of the third transistor to the eighth active layer 380b of the eighth transistor of the pixel circuit 11b may be symmetrical with respect to the first centerline 00′. The third active layer 330a of the third transistor, the fourth active layer 340a of the fourth transistor, the fifth active layer 350a of the fifth transistor, the sixth active layer 360a of the sixth transistor, and the seventh active layer 370a of the seventh transistor of the pixel circuit 11a may be of an integrated structure. The third active layer 330b of the third transistor, the fourth active layer 340b of the fourth transistor, the fifth active layer 350b of the fifth transistor, the sixth active layer 360b of the sixth transistor, and the seventh active layer 370b of the seventh transistor of the pixel circuit 11b may be of an integrated structure. The eighth active layer 380a of the eighth transistor of the pixel circuit 11a may be located on a side of the seventh active layer 370a of the seventh transistor close to the fifth active layer 350a of the fifth transistor. The eighth active layer 380b of the eighth transistor of the pixel circuit 11b may be located on a side of the seventh active layer 370b of the seventh transistor close to the fifth active layer 350b of the fifth transistor.

In some examples, as shown in FIG. 8, the shapes of the third active layers 330a and 330b may be substantially n-shaped, and the shapes of the fifth active layers 350a and 350b, the seventh active layers 370a and 370b, and the eighth active layers 380a and 380b may be substantially L-shaped. The shapes of the fourth active layers 340a and 340b and the sixth active layers 360a and 360b may be substantially I-shaped. However, this embodiment is not limited thereto.

In some examples, as shown in FIG. 7 and FIG. 8, an orthographic projection of the third active layer 330a on the base substrate may be overlapped with an orthographic projection of one light shield electrode 2001 on the base substrate, and an orthographic projection of the third active layer 330b on the base substrate may be overlapped with an orthographic projection of the other light shield electrode 2001 on the base substrate.

In some examples, as shown in FIG. 8, the active layer of each transistor of a pixel circuit may include a channel region and a first region and a second region located on opposite sides of the channel region. For example, a first region of the first active layer 310a of the pixel circuit 11a and a first region of the first active layer 310b of the pixel circuit 11b may be connected to each other.

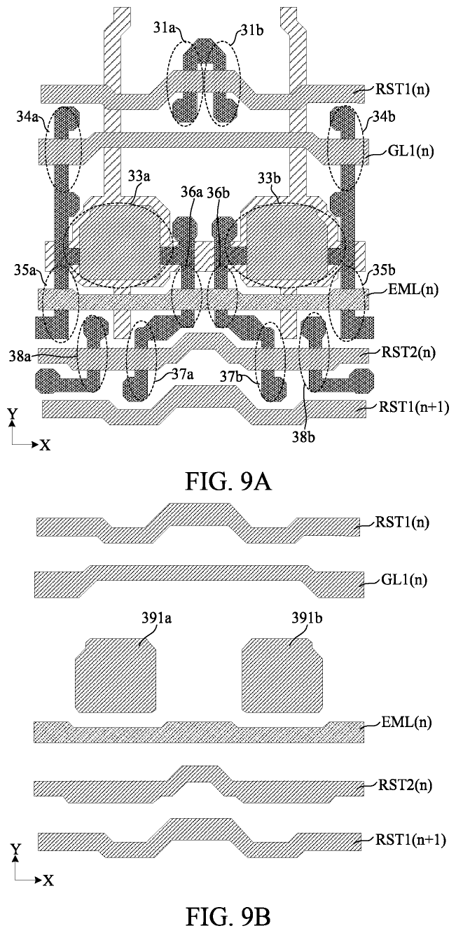

FIG. 9A is a schematic plan view of a display area after a first conductive layer is formed in FIG. 5. FIG. 9B is a schematic plan view of the first conductive layer in FIG. 9A. In some examples, as shown in FIG. 9A and FIG. 9B, the first conductive layer of the display area may at least include a first scan line GL1 (n), a light emitting control line EML (n), a first reset control line RST1 (n) and RST1 (n+1), a second reset control line RST2 (n), a first capacitance electrode plate 391a of a storage capacitor and gate electrodes of multiple second type transistors (e.g., including gate electrode of the first transistor 31a, gate electrodes of the third transistor 33a to the eighth transistor 38a) of the pixel circuit 11a, a first capacitance electrode plate 391b of a storage capacitor and gate electrodes of multiple second type transistors (e.g., including gate electrode of the first transistor 31b, gate electrodes of the third transistor 33b to the eighth transistor 38b) of the pixel circuit 11b.

In some examples, as shown in FIG. 9A and FIG. 9B, the first reset control line RST1 (n), the first scan line GL1 (n), the light emitting control line EML (n), and the second reset control line RST2 (n) may all extend in the first direction X. The first scan line GL1 (n) may be located between the first reset control line RST1 (n) and the light emitting control line EML (n) in the second direction Y and the second reset control line RST2 (n) may be located on a side of the light emitting control line EML (n) away from the first scan line GL1 (n).

In some examples, as shown in FIG. 7 and FIG. 9B, the gate electrode of the third transistor 33a of the pixel circuit 11a and the first capacitance electrode plate 391a of the storage capacitor of the pixel circuit 11a may be of an integrated structure. The gate electrode of the third transistor 33b of the pixel circuit 11b and the first capacitance electrode plate 391b of the storage capacitor of the pixel circuit 11b may be of an integrated structure. An orthographic projection of the first capacitance electrode plate 391a of the storage capacitor of the pixel circuit 11a on the base substrate may be within a range of an orthographic projection of one light shield electrode 2001 on the base substrate and an orthographic projection of the first capacitance electrode plate 391b of the storage capacitor of the pixel circuit 11b on the base substrate may be within a range of an orthographic projection of the other light shield electrode 2001 on the base substrate. In this example, the active layer of the third transistor is shielded by the light shield electrode, which can ensure the performance of the third transistor.

In some examples, as shown in FIG. 9A and FIG. 9B, the gate electrode of the fourth transistor 34a, the gate electrode of the fourth transistor 34b, and the first scan line GL1 (n) may be of an integrated structure. The gate electrode of the fifth transistor 35a, the gate electrode of the fifth transistor 35b, the gate electrode of the sixth transistor 36a, the gate electrode of the sixth transistor 36b, and the light emitting control line EML (n) may be of an integrated structure. The gate electrode of the seventh transistor 37a, the gate electrode of the seventh transistor 37b, the gate electrode of the eighth transistor 38a, the gate electrode of the eighth transistor 38b, and the second reset control line RST2 (n) may be of an integrated structure.

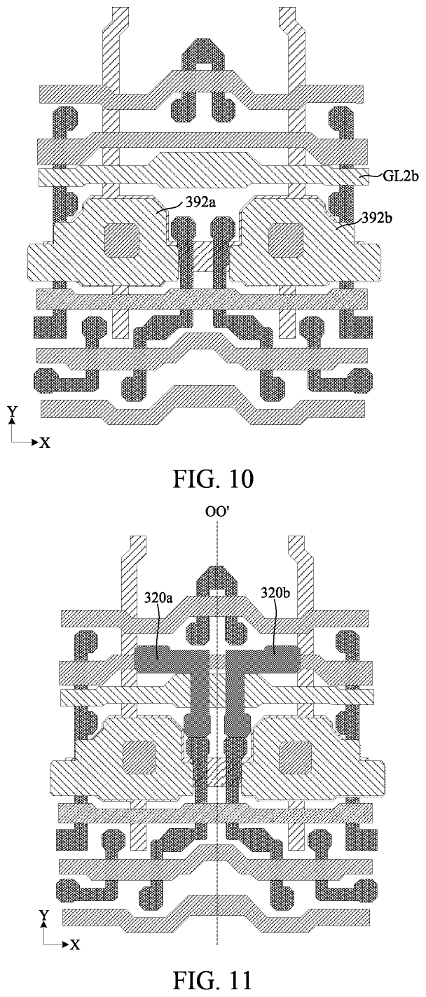

FIG. 10 is a schematic plan view of a display area after a second conductive layer is formed in FIG. 5. In some examples, as shown in FIGS. 5 to 10, the second conductive layer of the display area may include a second capacitance electrode plate 392a of the storage capacitor of the pixel circuit 11a, a second capacitance electrode plate 392b of the storage capacitor of the pixel circuit 11b, and a scan auxiliary line GL2b. The scanning auxiliary line GL2b may extend in the first direction X. An orthographic projection of the scan auxiliary line GL2b on the base substrate may be located on a side of an orthographic projection of the first scan line GL1 (n) on the base substrate close to the third transistor. The orthographic projection of the scan auxiliary line GL2b on the base substrate may not be overlapped with the orthographic projection of the first scan line GL1 (n) on the base substrate.

In some examples, as shown in FIGS. 5 to 10, an orthographic projection of the second capacitance electrode plate 392a of the storage capacitor of the pixel circuit 11a on the base substrate may be overlapped with an orthographic projection of the first capacitance electrode plate 391a of the storage capacitor of the pixel circuit 11a on the base substrate, a first hollow area may be provided in the second capacitance electrode plate 392a, and an orthographic projection of the first hollow area on the base substrate may be within a range of an orthographic projection of the first capacitance electrode plate 391a on the base substrate. An orthographic projection of the second capacitance electrode plate 392b of the storage capacitor of the pixel circuit 11b on the base substrate may be overlapped with an orthographic projection of the first capacitance electrode plate 391b of the storage capacitor of the pixel circuit 11b on the base substrate, a first hollow area may be provided in the second capacitance electrode plate 392b, and an orthographic projection of the first hollow area on the base substrate may be within a range of an orthographic projection of the first capacitance electrode plate 391b on the base substrate.

FIG. 11 is a schematic plan view of a display area after a second semiconductor layer is formed in FIG. 5. In some examples, as shown in FIGS. 5 to 11, the second semiconductor layer of the display area may include an active layers of the first type transistors of the pixel circuits 11a and 11b (e.g., a second active layer 320a of the second transistor of the pixel circuit 11a, a second active layer 320b of the second transistor of the pixel circuit 11b). The second active layer 320a of the second transistor of the pixel circuit 11a and the second active layer 320b of the second transistor of the pixel circuit 11b may be substantially symmetrical with respect to the first centerline 00′. An orthographic projection of the second active layer 320a on the base substrate may be substantially 7-shaped; an orthographic projection of the second active layer 320b on the base substrate may be substantially inverted L-shaped. The orthographic projection of the second active layer 320a on the base substrate may be located between the orthographic projection of the first active layer 310a on the base substrate and an orthographic projection of the sixth active layer 360a on the base substrate in the second direction Y; the orthographic projection of the second active layer 320b on the base substrate may be located between the orthographic projection of the first active layer 310b on the base substrate and an orthographic projection of the sixth active layer 360b on the base substrate in the second direction Y. An orthographic projection of the scan auxiliary line GL2b on the base substrate may be overlapped with the orthographic projection of the second active layer 320a and the orthographic projection of the second active layer 320b on the base substrate. The scan auxiliary line GL2b may be used as the bottom gate of the second transistor and may also shield the channel region of the second transistor to avoid affecting the performance of the second transistor.

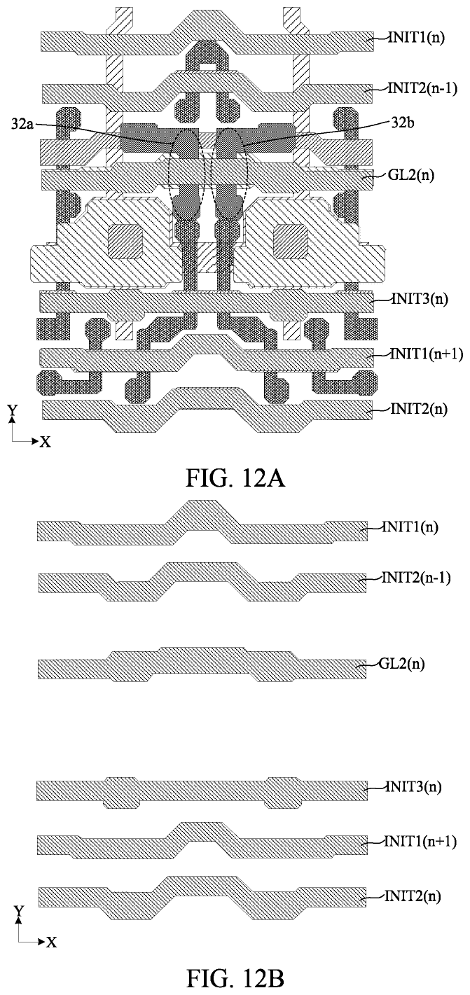

FIG. 12A is a schematic plan view of a display area after a third conductive layer is formed in FIG. 5. FIG. 12B is a schematic plan view of the third conductive layer in FIG. 12A. In some examples, as shown in FIGS. 5 to 12B, the third conductive layer of the display area may include a gate electrode of a first type transistor of the pixel circuit (including, for example, a gate electrode of a second transistor 32a, a gate electrode of a second transistor 32b), a second scan line GL2 (n), a first initial signal line INIT1 (n) and INIT1 (n+1), a second initial signal line INIT2 (n−1) and INIT2 (n), and a third initial signal line INIT3 (n). Herein, the second scan line GL2 (n), the first initial signal lines INIT1 (n) and INIT1 (n+1), the second initial signal lines INIT2 (n−1) and INIT2 (n), and the third initial signal line INIT3 (n) may all extend in the first direction X. The first initial signal line INIT1 (n), the second scan line GL2 (n), the third initial signal line INIT3 (n), and the second initial signal line INIT2 (n) may be sequentially disposed in the second direction Y. An orthographic projection of the second scan line GL2 (n) on the base substrate may be overlapped with the orthographic projection of the scan auxiliary line GL2b on the base substrate. The gate electrode of the second transistor 32a, the gate electrode of the second transistor 32b, and the second scan line GL2 (n) may be of an integrated structure. For example, the second scan line GL2 (n) and the scan auxiliary line GL2b may be configured to transmit a second scan signal. The second scan line GL2 (n) and the scan auxiliary line GL2b may be electrically connected in a peripheral area. However, this embodiment is not limited thereto.

In some examples, as shown in FIG. 9A and FIG. 12A, an orthographic projection of the second initial signal line INIT2 (n−1) on the base substrate may be overlapped with an orthographic projection of the first reset control line RST1 (n) on the base substrate. An orthographic projection of the third initial signal line INIT3 (n) on the base substrate may be overlapped with an orthographic projection of the light emitting control line EML (n) on the base substrate. An orthographic projection of the first initial signal line INIT1 (n+1) on the base substrate may be overlapped with an orthographic projection of the second reset control line RST2 (n) on the base substrate. An orthographic projection of the second initial signal line INIT2 (n) on the base substrate may be overlapped with an orthographic projection of the first reset control line RST1 (n+1) on the base substrate. A wiring arrangement of this example can reduce the space occupied by pixel circuits.

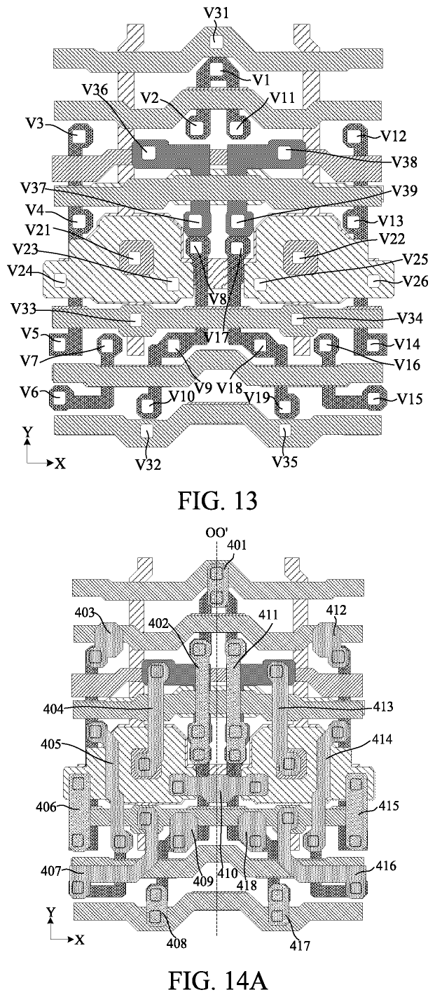

FIG. 13 is a schematic plan view of a display area after a sixth insulation layer is formed in FIG. 5. In some examples, as shown in FIGS. 5 to 13, the sixth insulation layer of the display area may be provided with multiple vias, for example, may include a first type of vias exposing a surface of the first semiconductor layer (e.g., including a first via V1 to a nineteenth via V19), a second type of vias exposing a surface of the first conductive layer (e.g., including a twenty-first via V21 and a twenty-second via V22), a third type of vias exposing a surface of the second conductive layer (e.g., including a twenty-third via V23 to a twenty-sixth via V26), a fourth type of vias exposing a surface of the second semiconductor layer (e.g., including a thirty-sixth via V36 to a thirty-ninth via V39), and a fifth type of vias exposing a surface of the third conductive layer (e.g., including a thirty-first via V31 to a thirty-fifth via V35). For example, the fourth type of vias and the fifth type of vias may be formed by a same patterning process and the first type of vias, the second type of vias, and the third type of vias may be formed by a same patterning process. This embodiment is not limited thereto.

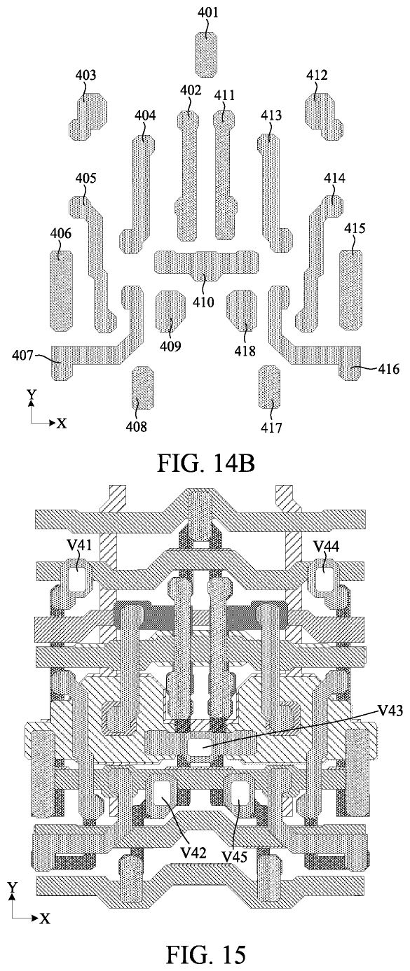

FIG. 14A is a schematic plan view of a display area after a fourth conductive layer is formed in FIG. 5. FIG. 14B is a schematic plan view of the fourth conductive layer in FIG. 14A. In some examples, as shown in FIGS. 14A to 14B, the fourth conductive layer of the display area may include multiple pixel connection electrodes (e.g., including a first pixel connection electrode 401 to an eighteenth pixel connection electrode 418).

In some examples, as shown in FIGS. 5 to 14B, the first pixel connection electrode 401 may be electrically connected with one end of the first active layer 310a of the first transistor 31a through the first via V1, and may also be electrically connected with the first initial signal line INIT1 (n) through the thirty-first via V31. The second pixel connection electrode 402 may be electrically connected with the other end of the first active layer 310a of the first transistor 31a through the second via V2, may also be electrically connected with one end of the second active layer 320a of the second transistor 32a through the thirty-seventh via V37, and may also be electrically connected with one end of the sixth active layer 360a of the sixth transistor 36a through the eighth via V8. The third pixel connection electrode 403 may be electrically connected with one end of the fourth active layer 340a of the fourth transistor 34a through the third via V3. The fourth pixel connection electrode 404 may be electrically connected with the other end of the second active layer 320a of the second transistor 32a through the thirty-sixth via V36, and may also be electrically connected with the gate electrode of the third transistor 33a through the twenty-first via V21. The fifth pixel connection electrode 405 may be electrically connected with the other end of the fourth active layer 340a of the fourth transistor 34a through the fourth via V4, and may also be electrically connected with one end of the eighth active layer 380a of the eighth transistor 38a through the seventh via V7. The sixth pixel connection electrode 406 may be electrically connected with the fifth active layer 350a of the fifth transistor 35a through the fifth via V5, and may also be electrically connected with the second capacitance electrode plate 392a of the storage capacitor through the twenty-fourth via V24. The seventh pixel connection electrode 407 may be electrically connected with the other end of the eighth active layer 380a of the eighth transistor 38a through the sixth via V6, and may also be electrically connected with the third initial signal line INIT3 (n) through the thirty-third via V33. The eighth pixel connection electrode 408 may be electrically connected with the seventh active layer 370a of the seventh transistor 37a through the tenth via V10, and may also be electrically connected with the second initial signal line INIT2 (n) through the thirty-second via V32. The ninth pixel connection electrode 409 may be electrically connected with the other end of the sixth active layer 360a of the sixth transistor 36a through the ninth via V9. The tenth pixel connection electrode 410 may be electrically connected with the second capacitance electrode plate 392a of the storage capacitor of the pixel circuit 11a through the twenty-third via V23, and may also be electrically connected with the second capacitance electrode plate 392b of the storage capacitor of the pixel circuit 11b through the twenty-fifth via V25.

In some examples, the eleventh pixel connection electrode 411 may be electrically connected with the first active layer 310b of the first transistor 31b through the eleventh via V11, may also be electrically connected with one end of the second active layer 320b of the second transistor 32b through the thirty-ninth via V39, and may also be electrically connected with one end of the sixth active layer 360b of the sixth transistor 36b through the seventeenth via V17. The twelfth pixel connection electrode 412 may be electrically connected with one end of the fourth active layer 340b of the fourth transistor 34b through the twelfth via V12. The thirteenth pixel connection electrode 413 may be electrically connected with the other end of the second active layer 320b of the second transistor 32b through the thirty-eighth via V38, and may also be electrically connected through the gate electrode of the third transistor 33b. The fourteenth pixel connection electrode 414 may be electrically connected with the other end of the fourth active layer 340b of the fourth transistor 34b through the thirteenth via V13, and may also be electrically connected with one end of the eighth active layer 380b of the eighth transistor 38b through the sixteenth via V16. The fifteenth pixel connection electrode 415 may be electrically connected with the fifth active layer 350b of the fifth transistor 35b through the fourteenth via V14, and may also be electrically connected with the second capacitance electrode plate 392b of the storage capacitor through the twenty-sixth via V26. The sixteenth pixel connection electrode 416 may be electrically connected with the other end of the eighth active layer 380b of the eighth transistor 38b through the fifteenth via V15, and may also be electrically connected with the third initial signal line INIT3 (n) through the thirty-fourth via V34. The seventeenth pixel connection electrode 417 may be electrically connected with the seventh active layer 370b of the seventh transistor 37b through the nineteenth via V19, and may also be electrically connected with the second initial signal line INIT2 (n) through the thirty-fifth via V35. The eighteenth pixel connection electrode 418 may be electrically connected with the other end of the sixth active layer 360b of the sixth transistor 36b through the eighteenth via V18.

In some examples, as shown in FIG. 14A, the second pixel connection electrode 402 and the eleventh pixel connection electrode 411 may be substantially symmetrical with respect to the first centerline 00′; the third pixel connection electrode 403 and the twelfth pixel connection electrode 412 may be substantially symmetrical with respect to the first centerline 00′; the fourth pixel connection electrode 404 and the thirteenth pixel connection electrode 413 may be substantially symmetrical with respect to the first centerline 00′; the fifth pixel connection electrode 405 and the fourteenth pixel connection electrode 414 may be substantially symmetrical with respect to the first centerline 00′; the sixth pixel connection electrode 406 and the fifteenth pixel connection electrode 415 may be substantially symmetrical with respect to the first centerline 00′; the seventh pixel connection electrode 407 and the sixteenth pixel connection electrode 416 may be substantially symmetrical with respect to the first centerline 00′; and the eighth pixel connection electrode 408 and the seventeenth pixel connection electrode 417 may be substantially symmetrical with respect to the first centerline 00′; the ninth pixel connection electrode 409 and the eighteenth pixel connection electrode 418 may be substantially symmetrical with respect to the first centerline 00′; the first pixel connection electrode 401 may be substantially symmetrical with respect to the first centerline 00′; and the tenth pixel connection electrode 410 may be substantially symmetrical with respect to the first centerline 00′.

FIG. 15 is a schematic plan view of a display area after a seventh insulation layer is formed in FIG. 5. In some examples, as shown in FIG. 15, multiple vias may be opened in the seventh insulation layer of the display area, for example, which may include a forty-first via V41 to a forty-fifth via V45. The seventh insulation layer in the forty-first via V41 to the forty-fifth via V45 may be removed to expose a surface of the fourth conductive layer.

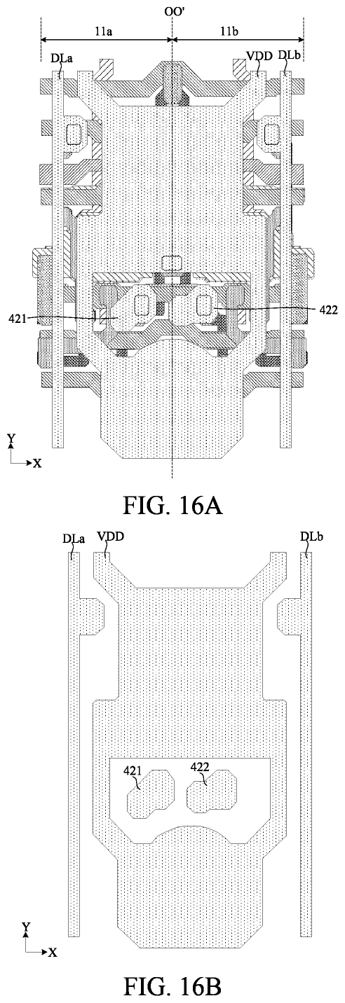

FIG. 16A is a schematic plan view of a display area after a fifth conductive layer is formed in FIG. 5. FIG. 16B is a schematic plan view of the fifth conductive layer in FIG. 16A. In some examples, as shown in FIGS. 5 to 16B, the fifth conductive layer of the display area may at least include a first power line VDD, a first data line DLa, a second data line DLb, a first anode connection electrode 421, and a second anode connection electrode 422. The first power line VDD may be electrically connected with the tenth pixel connection electrode 410 through the forty-third via V43, so that a first voltage signal is provided to the pixel circuits 11a and 11b. The first data line DLa may be electrically connected with the third pixel connection electrode 403 through the forty-first via V41, so that a data signal is provided to the pixel circuit 11a. The second data line DLb may be electrically connected with the twelfth pixel connection electrode 412 through the forty-fourth via V44, so that a data signal is provided to the pixel circuit 11b. The first anode connection electrode 421 may be electrically connected with the ninth pixel connection electrode 409 through the forty-second via V42 and the first anode connection electrode 421 may subsequently be electrically connected with the anode 311 of the light emitting element. The second anode connection electrode 422 may be electrically connected with the eighteenth pixel connection electrode 418 through the forty-fifth via V45 and the second anode connection electrode 422 may subsequently be electrically connected with the anode 312 of the other light emitting element.

In some examples, as shown in FIG. 16A, the first data line DLa and the second data line DLb may be substantially symmetrical with respect to the first centerline 00′. The first data line DLa and the second data line DLb may extend in the second direction Y and are located on two opposite sides of the first power line VDD in the first direction X. The first power line VDD may extend in the second direction Y and may have a second hollow area. The first anode connection electrode 421 and the second anode connection electrode 422 may be located in the second hollow area. This example can facilitate a transmission stability of the first voltage signal by increasing a width of the first power line VDD.

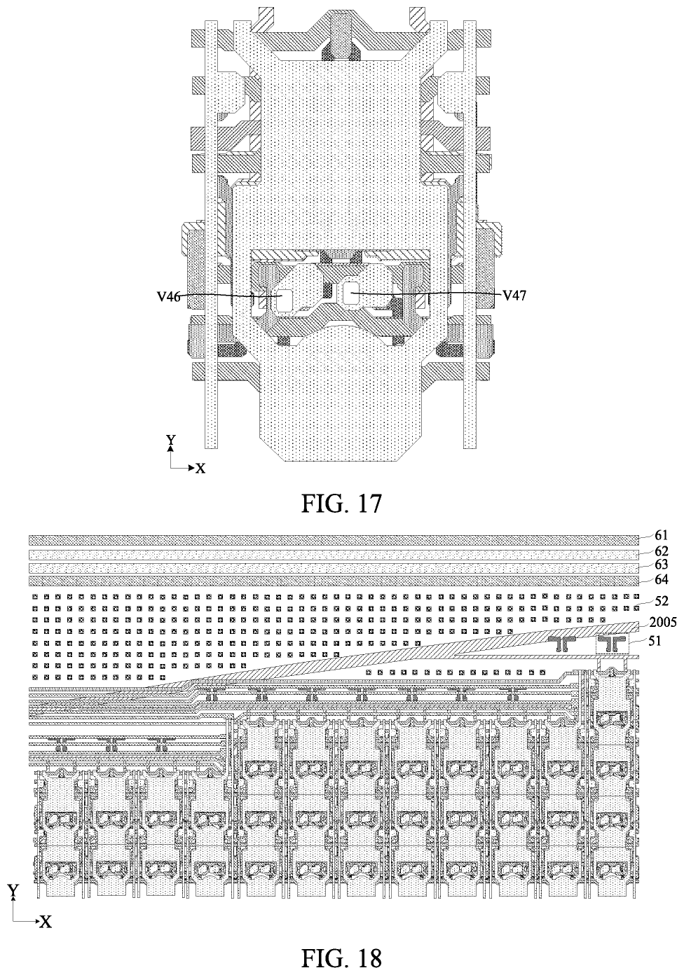

FIG. 17 is a schematic plan view of a display area after an eighth insulation layer is formed in FIG. 5. In some examples, as shown in FIG. 17, multiple vias may be opened in the eighth insulation layer of the display area, for example, may include a forty-sixth via V46 and a forty-seventh via V47. The eighth insulation layer in the forty-sixth via V46 and the forty-seventh via V47 may be removed to expose a surface of the fifth conductive layer.

In some examples, as shown in FIGS. 5 to 17, the anode 311 may be electrically connected with the first anode connection electrode 421 through the forty-sixth via V46, so that an electrical connection with the pixel circuit 11a is achieved. The Anode 312 may be electrically connected with the second anode connection electrode 422 through the forty-seventh via V47, so that an electrical connection with the pixel circuit 11b is achieved.

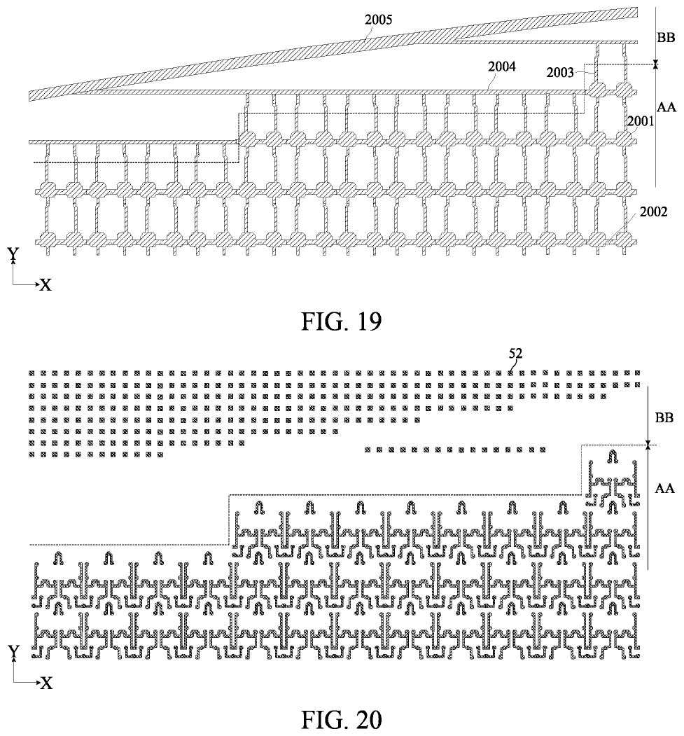

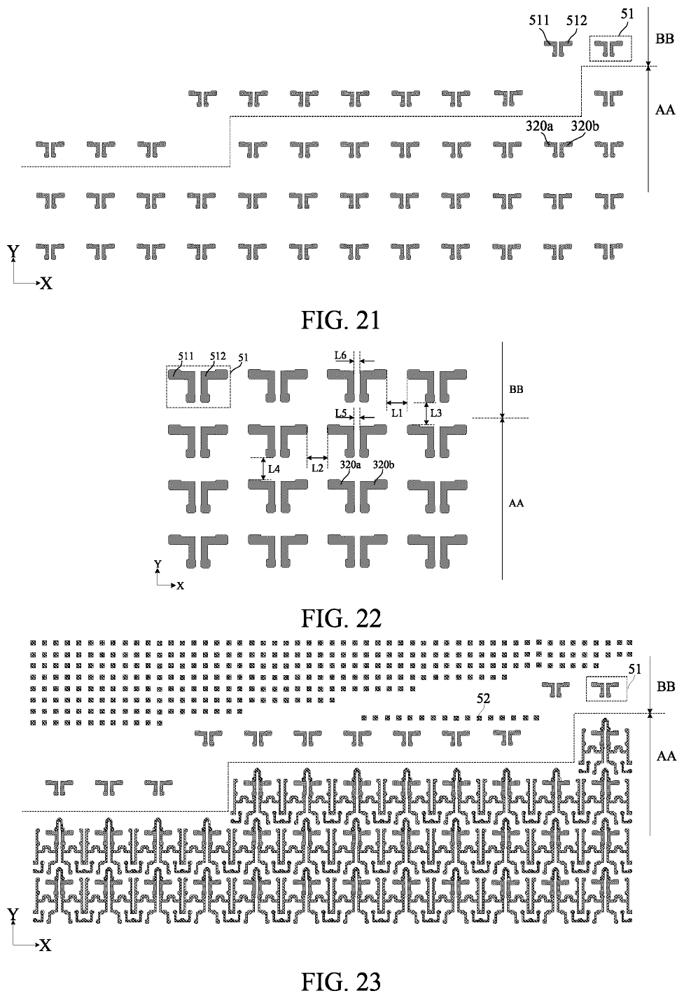

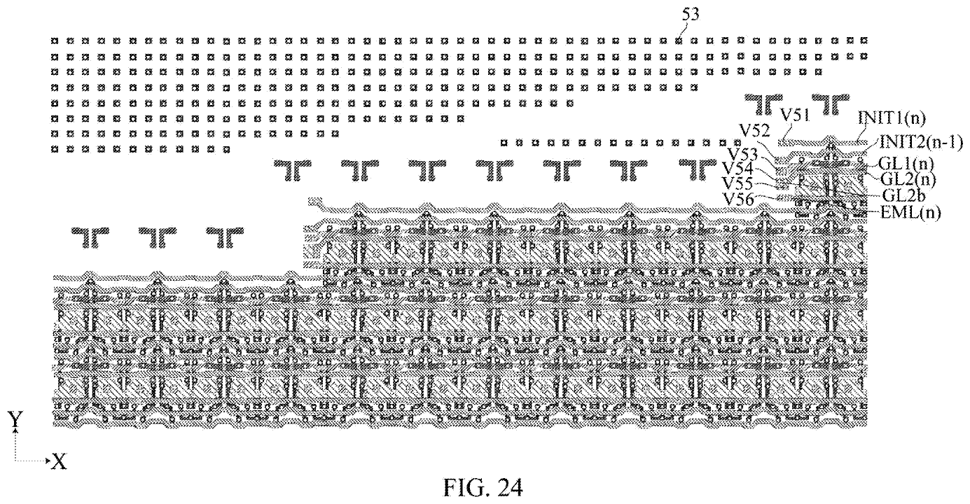

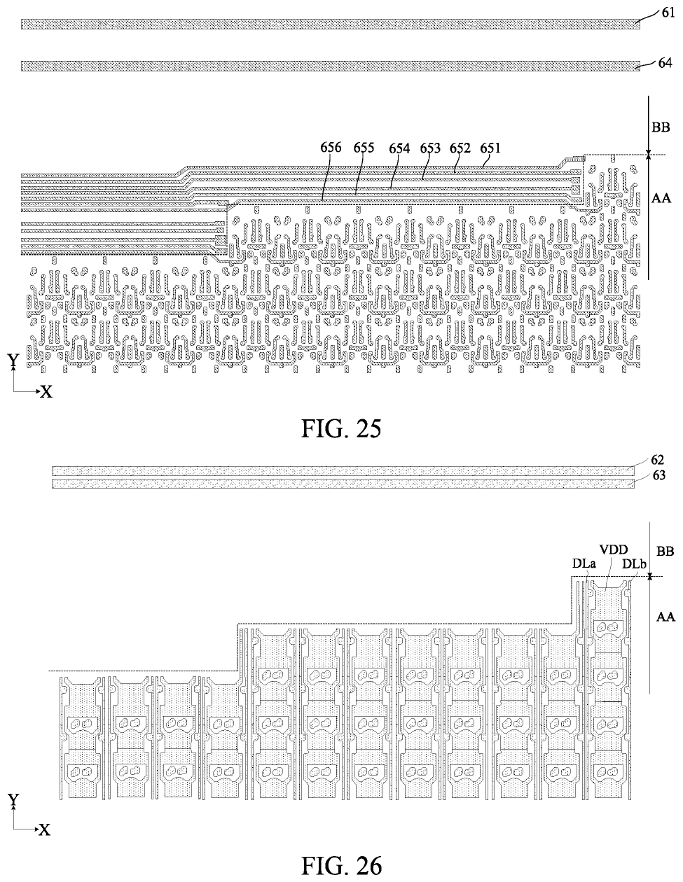

FIG. 18 is a schematic partial enlarged view of an area D1 in FIG. 2. The circuit structure layer of the display area and at least part of the circuit structure of the first corner C1 are illustrated in FIG. 18. FIG. 19 is a schematic plan view of a light shield layer in FIG. 18. FIG. 20 is a schematic plan view of a first semiconductor layer in FIG. 18. FIG. 21 is a schematic plan view of a second semiconductor layer in FIG. 18. FIG. 22 is a partial schematic view of the second semiconductor layer in FIG. 21. FIG. 23 is a schematic plan view of a first semiconductor layer and a second semiconductor layer in FIG. 18. FIG. 24 is a schematic plan view of a display substrate after a sixth insulation layer is formed in FIG. 18. FIG. 25 is a schematic plan view of a fourth conductive layer in FIG. 18. FIG. 26 is a schematic plan view of a fifth conductive layer in FIG. 18.

In some examples, as shown in FIG. 18 and FIG. 19, the light shield layer of the bezel area BB may include a third light shield connection electrode 2004 and a light shield connection line 2005. The second light shield connection electrode 2003 of the display area AA may extend to the bezel area BB in the second direction Y and the adjacent second light shield connection electrodes 2003 in the bezel area BB may be electrically connected through the third light shield connection electrode 2004. Adjacent third light shield connection electrodes 2004 may be electrically connected through a light shield connection line 2005. The light shield layers of the display area AA and the bezel area BB may be of an integrated structure, for example, may be electrically connected with a first power line or a second power line.

In some examples, as shown in FIG. 18 and FIG. 20, the first semiconductor layer of the bezel area BB may at least include multiple second auxiliary blocks 52. The multiple second auxiliary blocks 52 may be arranged in an array in the first direction X and the second direction Y. The shapes of orthographic projections of the multiple second auxiliary blocks 52 on the base substrate may be substantially the same, for example, an orthographic projection of the second auxiliary blocks 52 on the base substrate may be rectangular, such as a square.

In some examples, as shown in FIG. 18 and FIG. 21, the second semiconductor layer of the bezel area BB may include multiple first auxiliary structure groups 51. Each first auxiliary structure group 51 may include two first auxiliary blocks 511 and 512 disposed adjacently in the first direction X. The first auxiliary block 511 and the second auxiliary block 512 may be symmetrical with respect to a centerline of the first auxiliary structure group 51 in the first direction X. The shape and size of the first auxiliary block 511 may be the same as the shape and size of the second active layer 320a of the second transistor of the pixel circuit 11a of one pixel circuit group in the display area AA, and the shape and size of the second auxiliary block 512 may be the same as the shape and size of the second active layer 320b of the second transistor of the pixel circuit 11b of one pixel circuit group in the display area AA.

In some examples, as shown in FIG. 21 and FIG. 22, a first auxiliary structure group 51 may be located at an edge of a column of pixel circuit groups. The first auxiliary structure group 51 may be aligned with and adjacent to a corresponding column of pixel circuit groups in the second direction Y. Or, a setting position of a first auxiliary structure group 51 may be left between the first auxiliary structure group 51 and the corresponding column of pixel circuit groups in the second direction Y. An edge of a row of pixel circuit groups may be provided with multiple first auxiliary structure groups 51 (i.e., a row of first auxiliary structure groups) arranged in a first direction X. However, this embodiment is not limited thereto. In some other examples, two or more first auxiliary structure groups may be provided at an edge of each column of pixel circuit groups.

In this example, multiple pixel circuit groups arranged along the first direction X may be referred to as a row of pixel circuit groups and multiple pixel circuit groups arranged along the second direction Y may be referred to as a column of pixel circuit groups. Multiple first auxiliary structure groups arranged along the first direction X may be referred to as a row of first auxiliary structure groups and multiple first auxiliary structure groups arranged along the second direction Y may be referred to as a column of first auxiliary structure groups.

In some examples, as shown in FIG. 21 and FIG. 22, a row of first auxiliary structure groups may be aligned with a corresponding row of pixel circuit groups in the first direction X. Any first auxiliary structure group 51 in each row of the first auxiliary structure groups may be aligned with a corresponding row of pixel circuit groups in the second direction Y. However, this embodiment is not limited thereto.

In some examples, as shown in FIG. 21 and FIG. 22, a pitch L1 between first auxiliary blocks of adjacent first auxiliary structure groups 51 in the first direction X (i.e., a pitch between a first auxiliary block 512 of a first auxiliary structure group 51 and a first auxiliary block 511 of adjacent first auxiliary structure groups 51) in the bezel area BB may be the same as a pitch L2 between second active layers of second transistors of adjacent pixel circuit groups in the first direction X (i.e., a pitch between a second active layer 320b of a second transistor of a pixel circuit group and a second active layer 320a of a second transistor of an adjacent pixel circuit group) in the display area AA. However, this embodiment is not limited thereto. In some other examples, the pitch between the first auxiliary blocks of at least two adjacent first auxiliary structure groups in the first direction X may be different from the pitch between the second active layers of the second transistors of the adjacent pixel circuit groups in the first direction X in the display area. For example, the pitch between the first auxiliary blocks of at least two adjacent first auxiliary structure groups in the first direction X may be greater than the pitch between the second active layers of the second transistors of the adjacent pixel circuit groups in the first direction X in the display area.

In some examples, as shown in FIG. 21 and FIG. 22, in the second direction Y, a pitch L3 between a first auxiliary block of a first auxiliary structure group 51 in the bezel area BB and a second active layer of a second transistor of an adjacent pixel circuit group may be the same as a pitch L4 between second active layers of second transistors of the adjacent pixel circuit groups in the display area AA. However, this embodiment is not limited thereto. In some other examples, in the second direction Y, a pitch between a first auxiliary block of at least one first auxiliary structure group 51 and a second active layer of a second transistor of an adjacent pixel circuit group may be different from a pitch between the second active layers of the second transistors of the adjacent pixel circuit groups in the display area AA. For example, in the second direction Y, the pitch between the first auxiliary block of the at least one first auxiliary structure group 51 and the second active layer of the second transistor of the adjacent pixel circuit group may be greater than the pitch between the second active layers of the second transistors of the adjacent pixel circuit groups in the display area AA.

In some examples, as shown in FIG. 21 and FIG. 22, a pitch L6 between a first auxiliary block 511 and a second auxiliary block 512 in a first auxiliary structure group 51 may be the same as a pitch L5 between a second active layer 320a of a second transistor and a second active layer 320b of another second transistor of a pixel circuit group in the display area AA. In some examples, as shown in FIGS. 18 to 23, in the bezel area BB, in the second direction Y, multiple second auxiliary blocks 52 may be located on a side of a first auxiliary structure group 51 away from the display area AA. First auxiliary structure groups 51 may be arranged on the periphery of the pixel circuit along edges of the display area AA and multiple second auxiliary blocks 52 may be arranged on the periphery of the first auxiliary structure groups 51 along edges of the display area AA.

In some examples, as shown in FIG. 24, multiple vias may be opened in the sixth insulation layer in the bezel area BB, including, for example, a fifty-first via V51 to a fifty-sixth via V56, and multiple first auxiliary vias 53. The sixth insulation layer in the fifty-first via V51 may be removed to expose an end surface of a first initial signal line INIT1 (n) located in the third conductive layer and extending from the display area to the bezel area. The sixth insulation layer in the fifty-second via V52 may be removed to expose an end surface of a second initial signal line INIT2 (n−1) located in the third conductive layer and extending from the display area to the bezel area. The sixth insulation layer, the fifth insulation layer, the fourth insulation layer, and the third insulation layer in the fifty-third via V53 may be removed to expose an end surface of a first scan line GL1 (n) located in the first conductive layer and extending from the display area to the bezel area. The sixth insulation layer, the fifth insulation layer, and the fourth insulation layer in the fifty-fourth via V54 may be removed to expose an end surface of a scan auxiliary line GL2b located in the second conductive layer and extending from the display area to the bezel area. The sixth insulation layer in the fifty-fifth via V55 may be removed to expose an end surface of the second scan line GL2 (n) located in the third conductive layer and extending from the display area to the bezel area. The sixth insulation layer, the fifth insulation layer, the fourth insulation layer, and the third insulation layer in the fifty-sixth via V56 may be removed to expose an end surface of the light emitting control line MEL (n) located in the first conductive layer and extending from the display area to the bezel area. The sixth insulation layer, the fifth insulation layer, the fourth insulation layer, the third insulation layer, and the second insulation layer in a first auxiliary via 53 may be removed to expose a surface of the second auxiliary block located in the first semiconductor layer. In some examples, the multiple first auxiliary vias 53 and the multiple second auxiliary blocks are in one-to-one correspondence. An orthographic projection of a first auxiliary via 53 on the base substrate may be within a range of an orthographic projection of a second auxiliary block on the base substrate. For example, an orthographic projection of first auxiliary via 53 on the base substrate may be circular or elliptical.

In some examples, as shown in FIG. 25, the fourth conductive layer of the bezel area may include multiple transmission lines (e.g., including a first transmission line 651 to a sixth transmission line 656), a first voltage line 61, and a fourth voltage line 64. The first transmission lines 651 to the sixth transmission lines 656 may extend in the first direction X and are sequentially disposed in the second direction Y. As shown in FIG. 24 and FIG. 25, the first transmission line 651 may be electrically connected with the first initial signal line INIT1 (n) through two fifty-first vias V51 arranged horizontally and configured to transmit a first initial signal. The second transmission line 652 may be electrically connected with the second initial signal line INIT2 (n−1) through two fifty-second vias V52 arranged horizontally and configured to transmit a second initial signal. The third transmission line 653 may be electrically connected with the first scan line GL1 (n) through two fifty-third vias V53 arranged horizontally and configured to transmit a first scan signal. The fourth transmission line 654 may be electrically connected with the scan auxiliary line GL2b through two fifty-fourth vias V54 arranged vertically, and may also be electrically connected with the second scan line GL2 (n) through two fifty-fifth vias V55 arranged vertically, and configured to transmit a second scan signal. The fifth transmission line 655 may be electrically connected with the light emitting control line EML (n) through two fifty-sixth vias V56 arranged horizontally and configured to transmit a light emitting control signal. The sixth transmission line 656 may be electrically connected with the seventh pixel connection electrode 407 of the display area (e.g. may be of an integrated structure) and configured to transmit a third initial signal to the display area. In some examples, the third transmission line 653, the fourth transmission line 654, and the fifth transmission line 655 may be electrically connected with the output end of a gate electrode drive circuit in the bezel area. The first voltage line 61 and the fourth voltage line 64 may be configured to supply a voltage signal to the gate electrode drive circuit disposed in the bezel area.

In some examples, as shown in FIG. 18 and FIG. 25, orthographic projections of multiple transmission lines on the base substrate may be overlapped with orthographic projections of multiple first auxiliary structure groups 51 on the base substrate. Since there is no electrical connection between a transmission line and a first auxiliary structure group, the first auxiliary structure group does not affect the signal transmission of the transmission line. In some other examples, multiple second auxiliary vias may be provided at positions of the first auxiliary structure groups which are not covered by other film layers, and the sixth insulation layer and the fifth insulation layer in the multiple second auxiliary vias may be removed to expose a surface of the first auxiliary block to improve a uniformity of the peripheral pattern.

In some examples, as shown in FIG. 26, the fifth conductive layer of the bezel area may include a second voltage line 62 and a third voltage line 63. The second voltage line 62 and the third voltage line 63 may be configured to supply a voltage signal to the gate electrode drive circuit disposed in the bezel area. The first voltage line 61 to the fourth voltage line 64 may be located on the periphery of the first auxiliary block and the second auxiliary block.

In some examples, the first reset control line and the second reset control line may extend into a bezel area on the right side of the display area and be electrically connected with a transmission line in the right bezel area to enable reception of a first reset control signal and a second reset control signal.

In this example, by disposing multiple first auxiliary blocks in the bezel area, it is possible to improve the situation that a key size or a characteristic of a transistor is abnormal due to the photolithography load effect or other process environment differences during the preparing process of the second semiconductor layer. By disposing multiple first auxiliary blocks in the bezel area, the pattern uniformity around the pixel circuit can be ensured, and the influence of the first auxiliary blocks on other signals can be avoided. By disposing multiple second auxiliary blocks and multiple first auxiliary vias, the consistency between the bezel area and the display area in the film preparing process can be ensured, and the product yield can be improved.

In some examples, multiple first auxiliary blocks may be provided at multiple corner positions, and the first auxiliary block may not be provided at 4 bezel positions, i.e., the upper, lower, left and right bezel positions, to achieve a narrow bezel design. However, this embodiment is not limited thereto. In some other examples, multiple first auxiliary blocks may be disposed around the display area to ensure a graphic uniformity around the display area and improve the situation of poor bright and dark spots at edges.

In some examples, the first auxiliary structure may include not only the first auxiliary block located in the second semiconductor layer, but also auxiliary blocks of the other film layers, for example, may include auxiliary blocks located in at least one of the first semiconductor layer, the first conductive layer, the second conductive layer, the third conductive layer, the fourth conductive layer, and the fifth conductive layer, so as to ensure edge pattern uniformity of the pixel circuit during the preparing of the other film layers and avoid the case that the photolithography loading effect or other process environment differences affect the characteristics of the transistor. The shape and size of an auxiliary block included in the first auxiliary structure can be consistent with the shape and size of a film structure of the corresponding pixel circuit, thereby ensuring pattern uniformity.

Exemplary description is made below for a preparation process of a display substrate. “Patterning processes” mentioned in the present disclosure include photoresist coating, mask exposure, development, etching, photoresist stripping, etc., for metal materials, inorganic materials or transparent conductive materials, and include organic material coating, mask exposure, development, etc., for organic materials. Deposition may be any one or more of sputtering, evaporation and chemical vapor deposition, coating may be any one or more of spray coating, spin coating and inkjet printing, and etching may be any one or more of dry etching and wet etching, the present disclosure is not limited thereto. A “thin film” refers to a layer of thin film made of a material on a base substrate by using deposition, coating, or other processes. If the “film” does not need to be processed through a patterning process in the entire preparing process, the “film” may also be called a “layer”. If the “film” needs to be processed through the patterning process in the entire preparing process, the “film” is called a “film” before the patterning process is performed and is called a “layer” after the patterning process is performed. At least one “pattern” is contained in the “layer” which has been processed through the patterning process.

“A and B are disposed in a same layer” described in the present specification refers to that A and B are formed simultaneously through a same patterning process. A “thickness” of a film layer is a dimension of the film layer in a direction perpendicular to the display substrate. “An orthographic projection of B is within a range of an orthographic projection of A” or “An orthographic projection of A contains an orthographic projection of B” means that the boundary of the orthographic projection of B falls within a range of the boundary of the orthographic projection of A, or the boundary of the orthographic projection of A is overlapped with the boundary of the orthographic projection of B.

In some examples, the preparing process of the display substrate may include the following operations.

(1) A base substrate is provided. In some examples, the base substrate may be a rigid base substrate, or may be a flexible base substrate. For example, the rigid base substrate may be made of, but not limited to, one or more of glass and quartz. The flexible base substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base substrate may include a first flexible material layer, a first inorganic material layer, a second flexible material layer and a second inorganic material layer that are stacked. The first flexible material layer and the second flexible material layer may be made of a material such as polyimide (PI), polyethylene terephthalate (PET), or a polymer soft film on which surface treatment is performed, and a material of the first inorganic material layer and the second inorganic material layer may be silicon nitride (SiNx) or silicon oxide (SiOx), etc., which are used to improve resistance to water and oxygen of the base substrate.

(2) A pattern of a light shield layer is formed. In some examples, a light shield film layer is deposited on the base substrate, and the light shield film layer is patterned through a patterning process to form the light shield layer disposed on the base substrate, as shown in FIG. 7 and FIG. 19.

(3) A first semiconductor layer is formed. In some examples, a first insulation thin film and a first semiconductor thin film are sequentially deposited on the base substrate, and the first semiconductor thin film is patterned through a patterning process to form a first insulation layer and the first semiconductor layer disposed on the first insulation layer, as shown in FIG. 8 and FIG. 20. In some examples, a material of the first semiconductor layer may be amorphous silicon (a-Si), polycrystalline silicon (p-Si), hexathiophene or polythiophene, or other materials.

(4) A first conductive layer is formed. In some examples, a second insulation thin film and a first conductive thin film are sequentially deposited on the base substrate on which the aforementioned structures are formed, and the first conductive thin film is patterned through a patterning process to form a second insulation layer and the first conductive layer disposed on the second insulation layer, as shown in FIG. 9A.

In some examples, after the first conductive layer is formed, the first conductive layer may be used as a shield to perform a conductive treatment on the first semiconductor layer. A region of the first semiconductor layer, which is shielded by the first conductive layer, forms channel regions of the multiple transistors, and a region of the first semiconductor layer, which is not shielded by the first conductive layer, is made to be conductive, that is, all of the first regions and the second regions of the active layers of the first type transistors are made to be conductive.

(5) A second conductive layer is formed. In some examples, a third insulation thin film and a second conductive thin film are sequentially deposited on the base substrate on which the aforementioned structures are formed, and the second conductive thin film is patterned through a patterning process to form a third insulation layer and the second conductive layer disposed on the third insulation layer, as shown in FIG. 10.

(6) A second semiconductor layer is formed. In some examples, a fourth insulation thin film and a second semiconductor thin film are sequentially deposited on the base substrate on which the aforementioned patterns are formed, and the second semiconductor thin film is patterned through a patterning process to form a fourth insulation layer and the second semiconductor layer disposed on the fourth insulation layer, as shown in FIG. 11 and FIG. 21. In some examples, a material of the second semiconductor layer may be IGZO.

(7) A third conductive layer is formed. In some examples, a fifth insulation thin film and a third conductive thin film are sequentially deposited on the base substrate on which the aforementioned patterns are formed, and the third conductive thin film is patterned through a patterning process to form a fifth insulation layer and the third conductive layer disposed on the fifth insulation layer, as shown in FIG. 12A.

(8) A sixth insulation layer is formed. In some examples, a sixth insulation thin film is deposited on the base substrate on which the aforementioned patterns are formed, and the sixth insulation thin film is patterned through a patterning process to form the sixth insulation layer, as shown in FIG. 13 and FIG. 24.

(9) A fourth conductive layer is formed. In some examples, a fourth conductive thin film is deposited on the base substrate on which the aforementioned patterns are formed, and the fourth conductive thin film is patterned through a patterning process to form the fourth conductive layer on the sixth insulation layer, as shown in FIG. 14A and FIG. 25.

(10) A seventh insulation layer is formed. In some examples, a seventh insulation thin film is coated on the base substrate on which the aforementioned patterns are formed, and the seventh insulation thin film is patterned through a patterning process to form the seventh insulation layer, as shown in FIG. 15.

(11) A fifth conductive layer is formed. In some examples, a fifth conductive thin film is deposited on the base substrate on which the aforementioned patterns are formed, and the fifth conductive thin film is patterned through a patterning process to form the fifth conductive layer on the seventh insulation layer, as shown in FIG. 16A and FIG. 26.

(12) An eighth insulation layer, a light emitting structure layer and an encapsulation structure layer are sequentially formed.

In some examples, an eighth insulation thin film is coated on the base substrate on which the aforementioned patterns are formed, and the eighth insulation thin film is patterned through a patterning process to form the eighth insulation layer. Subsequently, an anode thin film is deposited on the base substrate on which the aforementioned patterns are formed, and the anode thin film is patterned through a patterning process to form an anode layer. Then, coating with a pixel definition thin film is performed and a pixel definition layer is formed by masking, exposure and development processes. The pixel definition layer may be formed with multiple pixel openings exposing the anode layer. An organic emitting layer is formed in the pixel openings formed earlier, and the organic light emitting layer is connected with the anode layer. Subsequently, a cathode thin film is deposited, the cathode thin film is patterned through a patterning process to form a cathode layer, and the cathode layer is connected with the organic emitting layer. Then, the encapsulation structure layer is formed on the cathode layer, for example, the encapsulation structure layer may include a stacked structure of an inorganic material/an organic material/an inorganic material.

In some examples, the first conductive layer, the second conductive layer, the third conductive layer, the fourth conductive layer, and the fifth conductive layer may be made of a metal material, such as, any one or more of silver (Ag), copper (Cu), aluminum (Al), and molybdenum (Mo), or an alloy material of the above metals, such as, an aluminum-neodymium alloy (AlNd), or a molybdenum-niobium alloy (MoNb), which may be a single layer structure, or a multi-layer composite structure, such as, Mo/Cu/Mo, etc. The first insulation layer, the second insulation layer, the third insulation layer, the fourth insulation layer, the fifth insulation layer and the sixth insulation layer may be made of any one or more of Silicon Oxide (SiOx), Silicon Nitride (SiNx), and Silicon OxyNitride (SiON), and may be a single layer, a multi-layer, or a composite layer. The seventh insulation layer and the eighth insulation layer may be made of an organic material, such as polyimide, acrylic, or polyethylene terephthalate. The pixel definition layer may be made of an organic material, such as polyimide, acrylic, or polyethylene terephthalate. The anode layer may be made of a reflective material such as a metal and the cathode layer may be made of a transparent conductive material. However, this embodiment is not limited thereto.

A structure and a preparing process of the display substrate of this embodiment are merely illustrative. In some exemplary implementations, a corresponding structure may be changed and a patterning process may be increased or decreased according to actual needs. The preparing process of this exemplary embodiment may be implemented using an existing mature preparing device, and may be compatible well with an existing preparing process, simple in process implementation, easy to implement, high in a production efficiency, low in production cost, and high in a yield.

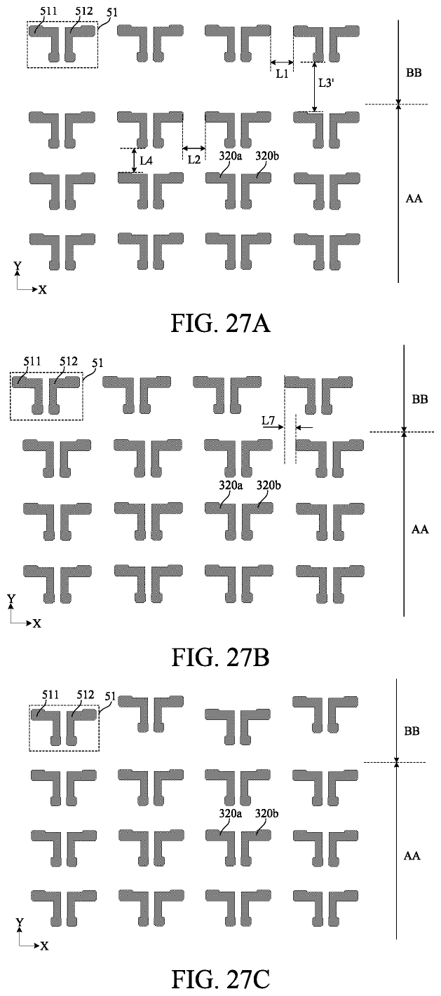

FIGS. 27A to 27C are other schematic plan views of a second semiconductor layer in FIG. 18.

In some examples, as shown in FIG. 27A, a first auxiliary structure group 51 of the bezel area may be aligned with a pixel circuit group of the display area in the second direction Y. In the second direction Y, a pitch L3′ between a first auxiliary block of a first auxiliary structure group 51 in the bezel area BB and a second active layer of a second transistor of the adjacent pixel circuit group may be greater than a pitch L4 between second active layers of second transistors of adjacent pixel circuit groups in the display area AA. For example, the pitch L3′ may be less than or equal to a length of a pixel circuit in the second direction Y. However, this embodiment is not limited thereto. Other descriptions of the first auxiliary structure group of this embodiment may refer to the description of the foregoing embodiments and therefore will not be repeated herein.

In some examples, as shown in FIG. 27B, a row of the first auxiliary structure groups 51 in the bezel area is misaligned with an adjacent row of pixel circuit groups in the first direction X. A misalignment distance between the first auxiliary structure group 51 and the pixel circuit group in the first direction X may be L7. For example, the misalignment distance L7 may be less than or equal to a length of one pixel circuit group in the first direction X. Other descriptions of the first auxiliary structure group of this embodiment may refer to the description of the foregoing embodiments and therefore will not be repeated herein.

In some examples, as shown in FIG. 27C, a row of first auxiliary structure groups 51 in the bezel area is not aligned in the first direction X, and adjacent first auxiliary structure groups 51 in the row of first auxiliary structure groups 51 are misaligned. For example, the misalignment distance between adjacent first auxiliary structure groups 51 may be less than or equal to a length of one pixel circuit in the second direction Y. Other descriptions of the first auxiliary structure group of this embodiment may refer to the description of the foregoing embodiments and therefore will not be repeated herein.

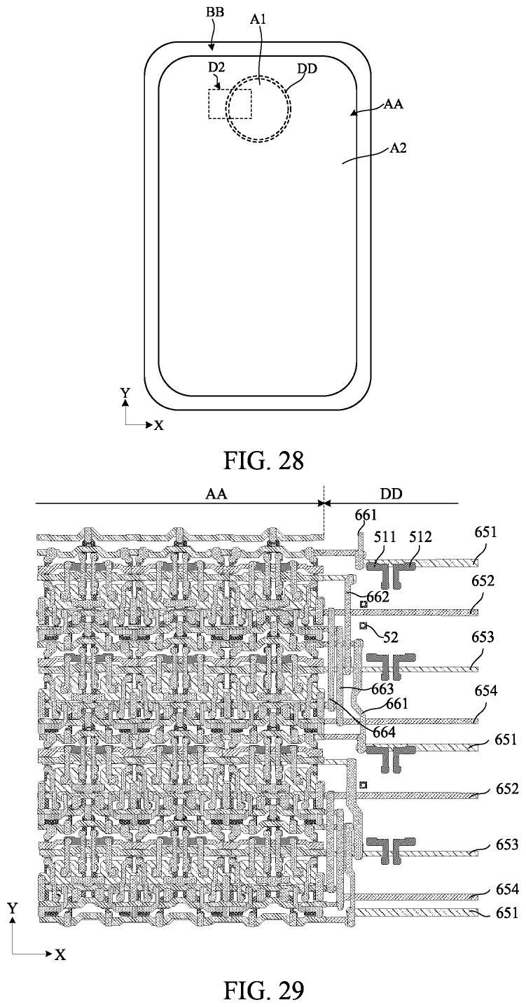

FIG. 28 is another schematic diagram of a display substrate according to at least one embodiment of the present disclosure. In some examples, as shown in FIG. 28, the display substrate of this example may include a display area AA and a bezel area BB surrounding the display area AA. The display area AA may include a first display area A1 and a second display area A2 located at least a side of the first display area A1, for example, the second display area A2 may surround the first display area A1. There is a transition area DD between the first display area A1 and the second display area A2.

In some examples, as shown in FIG. 28, the first display area A1 may be provided with multiple first light emitting elements and the second display area A2 may be provided with multiple pixel circuits and multiple second light emitting elements. The multiple pixel circuits may include multiple first pixel circuits and multiple second pixel circuits. At least one first pixel circuit may be electrically connected with at least one first light emitting element and configured to drive the at least one first light emitting element to emit light. At least one second pixel circuit may be electrically connected with at least one second light emitting element and configured to drive the at least one second light emitting element to emit light. For example, the multiple first pixel circuits and the multiple first light emitting elements may be electrically connected in one-to-one correspondence, and the multiple second pixel circuits and the multiple second light emitting elements may be electrically connected in one-to-one correspondence.

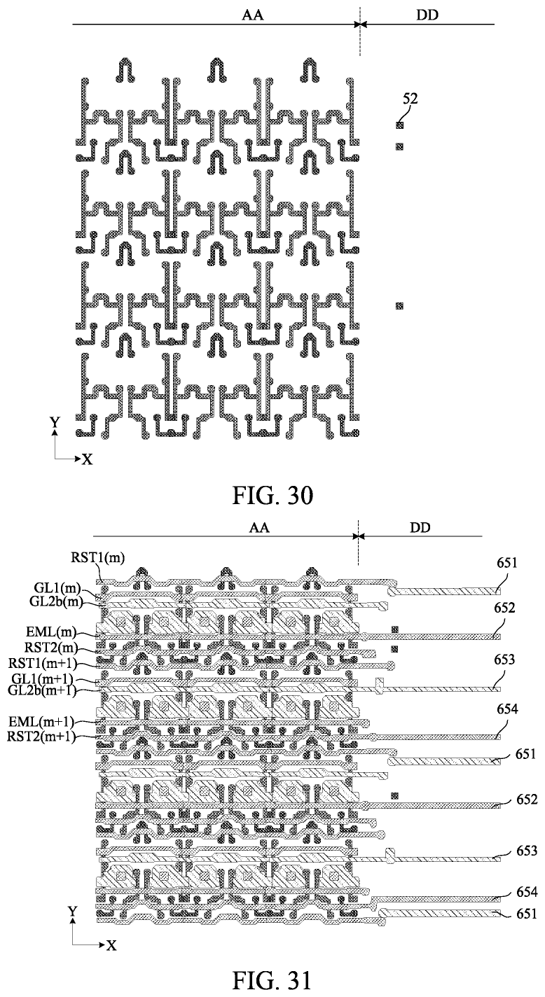

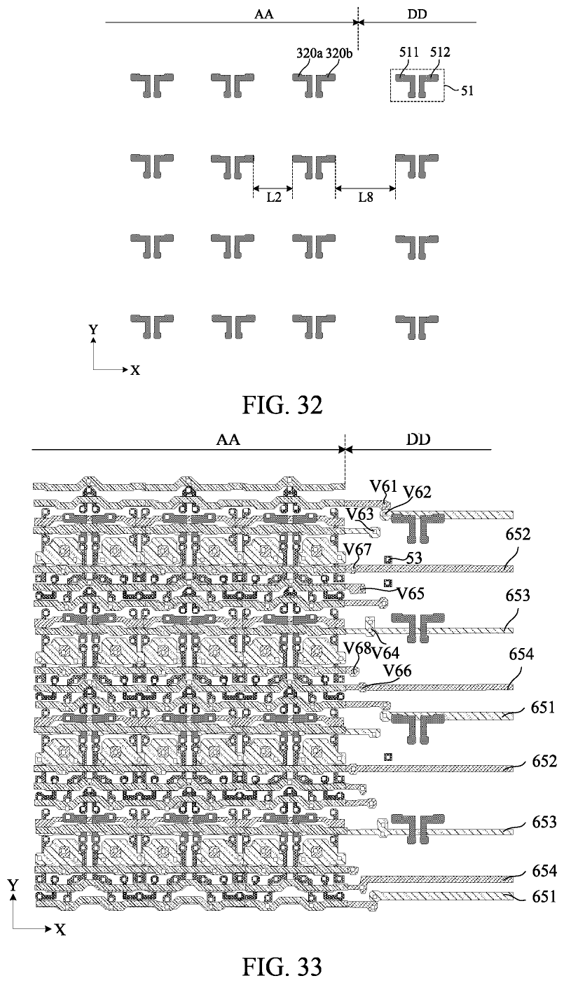

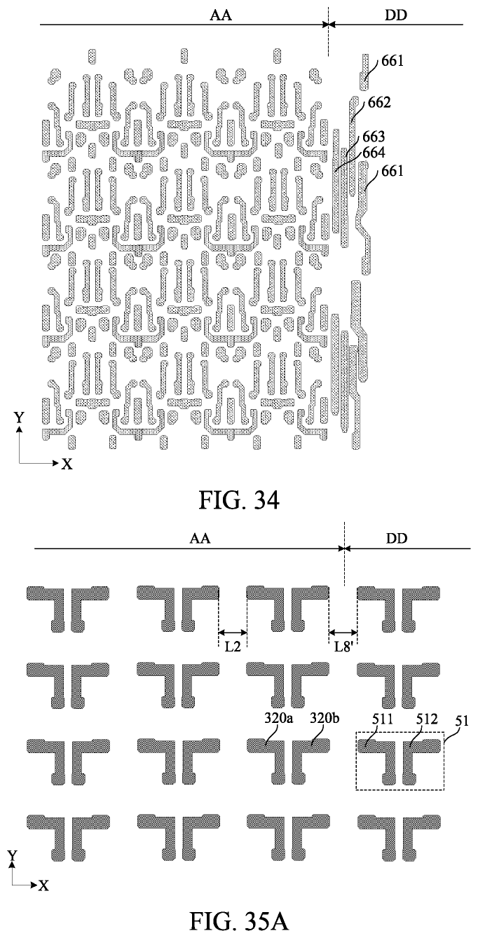

FIG. 29 is a schematic partial plan view of an area D2 in FIG. 28. FIG. 29 illustrates the film layer structures of the first semiconductor layer, the second semiconductor layer, the first conductive layer to the fourth conductive layer and leaves out the illustration of the light shield layer, the fifth conductive layer, and the light emitting structure layer. FIG. 30 is a schematic plan view of a first semiconductor layer in FIG. 29. FIG. 31 is a schematic plan view of a first semiconductor layer, a first conductive layer, and a second conductive layer in FIG. 29. FIG. 32 is a schematic plan view of a second semiconductor layer in FIG. 29. FIG. 33 is a schematic plan view after a sixth insulation layer is formed in FIG. 29. FIG. 34 is a schematic plan view of a fourth conductive layer in FIG. 29.

In some examples, as shown in FIG. 29, the transition area DD may include multiple first auxiliary structure groups and multiple second auxiliary blocks 52. Each first auxiliary structure may include a first auxiliary block 511 and a second auxiliary block 512 disposed adjacently in the first direction X. The multiple first auxiliary structure groups may be sequentially disposed in the second direction Y, for example, multiple first auxiliary structure groups in a column of first auxiliary structure groups may be aligned in the second direction Y.

In some examples, as shown in FIG. 29 and FIG. 30, the first semiconductor layer of the transition area may include multiple second auxiliary blocks 52. The multiple second auxiliary blocks 52 may be sequentially disposed in the second direction Y. A second auxiliary block 52 may be located between adjacent first auxiliary structure groups in the second direction Y. For example, one or more second auxiliary blocks 52 may be disposed between adjacent first auxiliary structure groups.

In some examples, as shown in FIG. 31, the first conductive layer of the transition area DD may include a second adapter line 652 and a fourth adapter line 654. The second conductive layer of the transition area DD may include a first adapter line 651 and a third adapter line 653. The first reset control lines RST1 (m) and RST1 (m+1) located in the first conductive layer in the display area AA may extend in the first direction X to the transition area DD. The scan auxiliary lines GL2b (m) and GL2b (m+1) located in the second conductive layer in the display area AA may extend in the first direction X to the transition area DD. The scan auxiliary line GL2b (m+1) may be integrally constructed with the third adapter line 653. The light emitting control lines EML (m) and EML (m+1) located in the first conductive layer in the display area AA may extend in the first direction X to the transition area DD. The light emitting control line EML (m) may be integrally constructed with the second adapter line 652. The second reset control lines RST2 (m) and RST2 (m+1) located in the first conductive layer in the display area AA may extend in the first direction X to the transition area DD. The second reset control line RST2 (m+1) may be integrally constructed with the fourth adapter line 654.

In some examples, as shown in FIG. 32, the second semiconductor layer of the transition area DD may include multiple first auxiliary structure groups 51. Each first auxiliary structure group 51 may include a first auxiliary block 511 and a second auxiliary block 512. A shape and size of a first auxiliary block 511 may be the same as a shape and size of a second active layer 320a of a second transistor of the pixel circuit group in the display area AA. A shape and size of a second auxiliary block 512 may be the same as a shape and size of a second active layer 320b of a second transistor of the pixel circuit group in the display area AA. A pitch L2 between second active layers of second transistors of the adjacent pixel circuit groups along the first direction X in the display area AA (i.e., a pitch between a second active layer 320b of a second transistor of a pixel circuit group and a second active layer 320a of a second transistor of an adjacent pixel circuit group) may be smaller than a pitch L8 between a first auxiliary block of a first auxiliary structure group 51 and a second active layer 320b of second transistor of the adjacent pixel circuit group.

In some examples, as shown in FIG. 32 and FIG. 33, an orthographic projection of the first auxiliary structure group 51 on the base substrate may be overlapped with an orthographic projection of an adapter line on the base substrate in the transition area DD. Multiple vias may be opened in the sixth insulation layer in the transition area DD, and may include, for example, a sixty-first via V61 to a sixty-eighth via V68, and a first auxiliary via 53. The sixth insulation layer, the fifth insulation layer, the fourth insulation layer, the third insulation layer, and the second insulation layer in the multiple first auxiliary vias 53 may be removed to expose a surface of a second auxiliary block 52 located in the first semiconductor layer. The multiple first auxiliary vias 53 and the multiple second auxiliary blocks 52 may be in one-to-one correspondence.

In some examples, as shown in FIG. 34, the fourth conductive layer in the transition area DD may include multiple connection electrodes (e.g., a first connection electrode 661 to a fourth connection electrode 664). The first connection electrode 661 may be electrically connected with the first reset control line RST1 (m) through the sixty-first via V61, may be electrically connected with the first adapter line 651 through the sixty-second via V62, and may extend in the second direction Y to be electrically connected with the previous first reset control line. The second connection electrode 662 may be electrically connected with the scan auxiliary line GL2b (m) through the sixty-third via V63, and may also be electrically connected with the third adapter line 653 through the sixty-fourth via V64. The third connection electrode 663 may be electrically connected with the second reset control line RST2 (m) through the sixty-fifth via V65, and may also be electrically connected with the fourth adapter line 654 through the sixty-sixth via V66. The fourth connection electrode 664 may be electrically connected with the light emitting control line EML (m) and the second adapter line 652 through the sixty-seventh via V67, and may also be electrically connected with the light emitting control line EML (m+1) through the sixty-eighth via V68.

In this example, the first adapter line 651 may be connected with the first reset control lines on both sides of the first display area along the first direction and is configured to transmit a first reset control signal; the second adapter line 652 may be connected with light emitting control lines on both sides of the first display area in the first direction and is configured to transmit a light emitting control signal; the third adapter line 653 may be connected with scan auxiliary lines on both sides of the first display area in the first direction and is configured to transmit a second scan signal; the fourth adapter line 654 may be connected with second reset control lines on both sides of the first display area in the first direction and is configured to transmit a second reset control signal.

In this example, by disposing multiple first auxiliary blocks in the transition area, it is possible to improve the situation that the key size or characteristic of the transistor is abnormal due to the photolithography load effect or other process environment differences during the preparing process of the second semiconductor layer. By disposing multiple first auxiliary blocks, the pattern uniformity around the pixel circuit can be ensured, and the influence of the first auxiliary blocks on other signals can be avoided. By disposing multiple second auxiliary blocks and multiple first auxiliary vias, the consistency between the transition area and the display area in the film preparing process can be ensured, and the product yield can be improved.

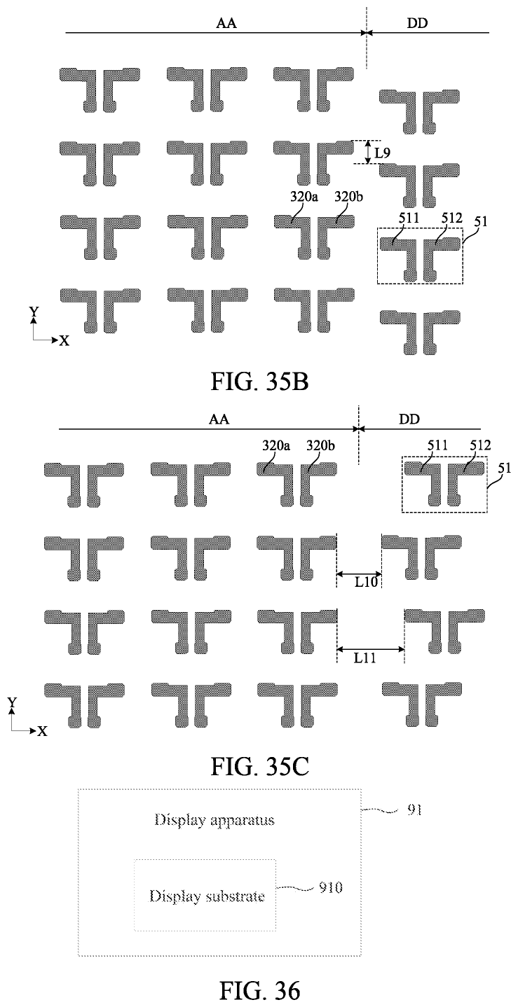

FIGS. 35A to 35C are other schematic plan views of a second semiconductor layer in FIG. 29.

In some examples, as shown in FIG. 35A, a column of first auxiliary structure groups 51 in the transition area DD may be aligned in the second direction Y. A pitch L8′ between a first auxiliary block of a first auxiliary structure group 51 and a second active layer 320b of a second transistor in the adjacent pixel circuit group may be substantially the same as a pitch L2 between second active layers of second transistors of adjacent pixel circuit groups in the first direction X in the display area AA (i.e., a pitch between a second active layer 320b of a second transistor of a pixel circuit group and a second active layer 320a of a second transistor of the adjacent pixel circuit group). Rest of the structure of the display substrate according to this embodiment may refer to descriptions of the aforementioned embodiments, and will not be repeated herein.

In some examples, as shown in FIG. 35B, a first column of auxiliary structure groups in the transition area DD is misaligned with an adjacent column of pixel circuit groups in the first direction X. The misalignment distance between a first auxiliary structure group 51 and an adjacent pixel circuit group in the second direction Y is L9. The misalignment distance L9 may be less than or equal to a length of a pixel circuit in the second direction Y. Rest of the structure of the display substrate according to this embodiment may refer to descriptions of the aforementioned embodiments, and will not be repeated herein.

In some examples, as shown in FIG. 35C, multiple first auxiliary structure groups 51 in a column of first auxiliary structure groups in the transition area DD may be misaligned in the first direction X. A pitch L10 between a first auxiliary structure group 51 in a column of first auxiliary structure groups and an adjacent pixel circuit group may be smaller than a pitch L11 between a first auxiliary structure group adjacent to the first auxiliary structure group 51 and an adjacent pixel circuit group in the second direction Y. Rest of the structure of the display substrate according to this embodiment may refer to descriptions of the aforementioned embodiments, and will not be repeated herein.

In some other examples, first auxiliary blocks may be provided in both the bezel area and the transition area of the display substrate to improve the situation that bright and dark spots at an edge in the bezel area and the transition area are poor due to photolithography load effect or other process environment differences.

FIG. 36 is a schematic diagram of a display apparatus according to at least one embodiment of the present disclosure. In some examples, as shown in FIG. 36, this embodiment provides a display apparatus 91, including a display panel 910 in the aforementioned embodiments. In some examples, the display panel 910 may be an OLED display substrate, a QLED display substrate, a Micro-LED display substrate, or a Mini-LED display substrate. The display apparatus 91 may be any product or component with a display function, such as a mobile phone, a tablet computer, a television, a display, a laptop computer, a digital photo frame, and a navigator. However, this embodiment is not limited thereto.

The drawings of the present disclosure only involve structures involved in the present disclosure, and other structures may refer to conventional designs. The embodiments of the present disclosure and features in the embodiments may be combined to each other to obtain new embodiments if there is no conflict. Those of ordinary skills in the art should understand that modifications or equivalent replacements may be made on the technical solutions of the present disclosure without departing from the spirit and scope of the technical solutions of the present disclosure, and shall all fall within the scope of the claims of the present disclosure.

1. A display substrate, comprising:
a base substrate, a plurality of pixel circuits and a plurality of first auxiliary structures disposed on the base substrate; wherein
the plurality of first auxiliary structures are located at edges of the plurality of pixel circuits, at least one first auxiliary structure of the plurality of first auxiliary structures is adjacent to at least one pixel circuit of the plurality of pixel circuits; the plurality of pixel circuits comprise at least one semiconductor layer located on the base substrate, and an orthographic projection of the at least one first auxiliary structure on the base substrate is at least partially identical to an orthographic projection of the at least one semiconductor layer of the at least one pixel circuit on the base substrate.

2. The display substrate according to claim 1, wherein the plurality of first auxiliary structures are arranged in a same manner as the plurality of pixel circuits.

3. The display substrate according to claim 2, wherein the plurality of pixel circuits are arranged in an array along a first direction and a second direction; the at least one first auxiliary structure is aligned with the plurality of pixel circuits in the first direction or in the second direction, or the at least one first auxiliary structure is misaligned with the plurality of pixel circuits in the first direction or in the second direction; the first direction intersects with the second direction.

4. The display substrate according to claim 1, wherein the plurality of pixel circuits comprise at least one pixel circuit group, the at least one pixel circuit group comprises two pixel circuits disposed adjacently in a first direction;
the plurality of first auxiliary structures comprise at least one first auxiliary structure group, the at least one first auxiliary structure group comprises two first auxiliary structures disposed adjacently in the first direction;
an orthographic projection of the at least one first auxiliary structure group on the base substrate is at least partially identical to an orthographic projection of the at least one semiconductor layer of the at least one pixel circuit group on the base substrate.

5. The display substrate according to claim 4, wherein two pixel circuits of the at least one pixel circuit group each comprises: at least one first type transistor; the semiconductor layer comprises an active layer of the at least one first type transistor; two first auxiliary structures of the at least one first auxiliary structure group each comprises: at least one first auxiliary block; the at least one first auxiliary block and the active layer of the first type transistor are of a same layer structure;
an orthographic projection of a first auxiliary block of the at least one first auxiliary structure group on the base substrate is identical to an orthographic projection of an active layer of a first type transistor of the at least one pixel circuit group on the base substrate.

6. The display substrate according to claim 5, wherein active layers of first type transistors of two pixel circuits of the at least one pixel circuit group are symmetrical with respect to a centerline of the pixel circuit group in the first direction, and first auxiliary blocks of two first auxiliary structures of the first auxiliary structure group are symmetrical with respect to a centerline of the first auxiliary structure group in the first direction.

7. The display substrate according to claim 5, wherein a pitch between active layers of first type transistors of two pixel circuits in the at least one pixel circuit group in the first direction is the same as a pitch between first auxiliary blocks of two first auxiliary structures in the at least one first auxiliary structure group in the first direction.

8. The display substrate according to claim 4, wherein the plurality of first auxiliary structure groups are located at edges of the plurality of pixel circuit groups in a second direction, and pitches between the plurality of first auxiliary structure groups and adjacent pixel circuit groups are same in the second direction; or, pitches between first auxiliary structure groups disposed at interval and adjacent pixel circuit groups in the second direction are same, and pitches between first auxiliary structure groups disposed adjacently and corresponding adjacent pixel circuit groups in the second direction are different; the second direction intersects with the first direction.

9. The display substrate according to claim 4, wherein the plurality of first auxiliary structure groups are located at edges of the plurality of pixel circuit groups in the first direction, and pitches between the plurality of first auxiliary structure groups and adjacent pixel circuit groups are same in the first direction; or, pitches between first auxiliary structure groups disposed at interval and adjacent pixel circuit groups in the first direction are same, and pitches between first auxiliary structure groups disposed adjacently and corresponding adjacent pixel circuit groups in the first direction are different.

10. The display substrate according to claim 4, wherein the at least one first auxiliary structure group is aligned with a plurality of pixel circuit groups arranged along the first direction in the first direction.

11. The display substrate according to claim 4, wherein the at least one first auxiliary structure group is aligned with a plurality of pixel circuit groups arranged along a second direction in the second direction, the second direction intersects with the first direction.

12. The display substrate according to claim 5, further comprising: a second auxiliary structure, wherein the second auxiliary structure comprises: a plurality of second auxiliary blocks located at edges of the plurality of pixel circuits and arranged in an array; orthographic projections of the plurality of second auxiliary blocks on the base substrate are not overlapped with an orthographic projection of the first auxiliary block on the base substrate.

13. The display substrate according to claim 12, wherein the plurality of second auxiliary blocks are located on a side of the first auxiliary block close to the base substrate.

14. The display substrate according to claim 12, wherein the pixel circuit further comprises: at least one second type transistor, the second type transistor and the first type transistor are of different transistor types; the plurality of second auxiliary blocks and an active layer of the second type transistor are of a same layer structure.

15. The display substrate according to claim 12, further comprising: a plurality of first auxiliary vias, wherein the plurality of first auxiliary vias and the plurality of second auxiliary blocks are in one-to-one correspondence, an orthographic projection of at least one first auxiliary via on the base substrate is within an range of an orthographic projection of a corresponding second auxiliary block on the base substrate.

16. The display substrate according to claim 1, wherein the base substrate comprises a display area and a bezel area located on a periphery of the display area; the plurality of first auxiliary structures are located in the bezel area, and the plurality of pixel circuits are located in the display area.

17. The display substrate according to claim 1, wherein the base substrate comprises: a display area; the display area comprises a first display area and a second display area located at least a side of the first display area; a transition area is provided between the first display area and the second display area; the plurality of pixel circuits are located in the second display area, and the plurality of first auxiliary structures are located in the transition area.

18. The display substrate according to claim 1, wherein in a direction perpendicular to the display substrate, the display substrate comprises: a first semiconductor layer, a first conductive layer, a second conductive layer, a second semiconductor layer, a third conductive layer, a fourth conductive layer, and a fifth conductive layer disposed sequentially on the base substrate; the plurality of first auxiliary structures at least comprise a first auxiliary block located in the second semiconductor layer.

19. A display apparatus, comprising a display substrate according to claim 1.

20. A preparing method for a display substrate, which is used for preparing the display substrate of claim 1, wherein the method comprises:
forming a plurality of pixel circuits and a plurality of first auxiliary structures on a base substrate;
wherein the plurality of first auxiliary structures are located at edges of the plurality of pixel circuits, at least one first auxiliary structure is adjacent to at least one pixel circuit, the plurality of pixel circuits comprise at least one semiconductor layer located on the base substrate, and an orthographic projection of the at least one first auxiliary structure on the base substrate is at least partially identical to an orthographic projection of the at least one semiconductor layer of the at least one pixel circuit on the base substrate.
